(19) United States
(12) Patent Application Publication
(10) Pub. No.: US 2025/0038470 A1
(43) Pub. Date: Jan. 30, 2025

(54) OPTOELECTRONIC DEVICE INCLUDING A VERTICAL-CAVITY SURFACE EMITTING LASER DIODE

(71) Applicant: Taiwan Semiconductor Manufacturing Company. Ltd., Hsinchu (TW)

(72) Inventors: ChunHao LIN, Tainan City (TW); Yun-Wei CHENG, Taipei City (TW); Kuo-Cheng LEE, Tainan City (TW)

(21) Appl. No.: 18/357,517

(22) Filed: Jul. 24, 2023

(51) Int. Cl. H01S 5/026; H01L 27/146; H01S 5/183

(52) U.S. Cl. CPC H01S 5/0262; H01L 27/1465; H01L 27/1469; H01L 27/14694; H01S 5/183

(57) ABSTRACT

Some implementations described herein include an optoelectronic device for a low-lighting application and techniques to form the optoelectronic device. The optoelectronic device includes near infrared light vertical-cavity surface emitting laser devices, near infrared light pixel sensors, and visible light pixel sensors. The near infrared light vertical-cavity surface emitting laser devices and the near infrared light pixel sensor include selectively grown epitaxial materials (e.g., silicon germanium, gallium arsenide, or another type III/V material) that improves a performance of the near infrared light vertical-cavity surface emitting laser devices, near infrared light pixel sensors.

### BACKGROUND

Complementary metal oxide semiconductor (CMOS) image sensor (CIS) devices utilize light-sensitive CMOS circuitry to convert light energy into electrical energy. The light-sensitive CMOS circuitry includes a photodiode formed in a silicon substrate. As the photodiode is exposed to light, an electrical charge is induced in the photodiode (referred to as a photocurrent). The photodiode may be coupled to a switching transistor, which is used to sample the charge of the photodiode. Colors may be determined by placing filters over the light-sensitive CMOS circuitry.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of a portion of an example optoelectronic device described herein.

FIG. 3 is a diagram of an example optoelectronic device described herein.

FIGS. 4A-4E are diagrams of an example implementation for forming a portion of an optoelectronic device including photodiodes.

FIG. 5A-5G are diagrams of an example implementation for forming a portion of an optoelectronic device including a laser emitting diode.

FIGS. 6A-6I are diagrams of an example implementation of joining optoelectronic devices to form an optoelectronic device including a vertical-cavity surface emitting laser.

FIG. 7 is a diagram of example components of a device associated with forming an optoelectronic device including a vertical-cavity surface emitting laser.

FIG. 8 is a flowchart of an example process associated with forming an optoelectronic device including a vertical-cavity surface emitting laser.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, an image detection system in a low-lighting environment includes a combination of discrete optoelectronic devices. For example, the image detection system may include discrete near infrared (NIR) light emitting diode (LED) devices for projecting NIR light waves onto a target (e.g., a target for a reflected image), discrete NIR pixel sensors for detecting NIR light waves reflected from the target, and discrete visible light (VIS) pixel sensors for detecting visible light waves reflected from the target. In addition to drawbacks related to the discrete devices consuming space within the system, silicon-based photodiodes of the NIR pixel sensors may have a low quantum efficiency (QE) performance.

An optoelectronic device may include structures using an epitaxially grown type III or type V material (e.g., a type III or type V periodic element). Type III and type V materials are considered as “wide-bandgap materials,” which have higher energy gaps compared to traditional semiconductors materials. This property enables type III and type V materials to absorb photons with higher energies, including those in the infrared region of the spectrum and, as a result, can significantly enhance a quantum efficiency of a photodiode. Further, type III and type V materials have a lower density of defects, which reduces the level of noise and increases the signal-to-noise ratio of the photodiode. Using type III or type V materials in light emitting laser diodes can lead to better emission of light. Further, using type III or type V materials in photodiodes can lead to a detection of light, especially for applications that require high sensitivity in low light conditions. In contrast to silicon-based photodiodes, type III and/or type V material-based photodiodes have improved light emission and detection capabilities that are beneficial in low light application including medical imaging, remote sensing, and communication technologies.

Some implementations described herein include an optoelectronic device for a low-lighting application and techniques to form the optoelectronic device. The optoelectronic device includes NIR vertical-cavity surface emitting laser devices (VC-SEL devices), NIR pixel sensors, and VIS pixel sensors. The NIR VC-SEL devices and the NIR pixel sensor include selectively grown epitaxial materials (e.g., silicon germanium (SiGe), gallium arsenide (GaAs), and/or another type III/V material) that improves a performance of the NIR VC-SEL devices and the NIR pixel sensors.

Furthermore, the NIR VC-SEL devices, the NIR pixel sensors, and the VIS pixel sensors are integrated in a single three-dimensional, complementary metal-oxide image sensor (3D-CIS) device. By combining the NIR VC-SEL devices, the NIR pixel sensors, and the VIS pixel sensors into a single 3D-CIS device, a complexity and/or number of manufacturing operations to form the image detection system is lesser relative to the complexity and/or number of manufacturing operations to form another image detection system using discrete NIR VC-SEL devices, the NIR pixel sensors, and the VIS light pixel sensors.

In this way, a performance (e.g., a QE) of the optoelectronic device including the NIR VC-SEL devices, the NIR pixel sensors, and the VIS pixel sensors is improved relative to another optoelectronic device including doped, silicon-based photodiode devices and/or LED devices. Improving the performance of the optoelectronic device increases a manufacturing yield, of the optoelectronic device, to a particular performance threshold. Additionally, combining the NIR VC-SEL devices, the NIR pixel sensors, and the VIS pixel sensors into a single 3D-CIS device reduces an overall device space (e.g., silicon) and/or image detection system space. By increasing the manufacturing yield and consuming less device space and/or image detection system space, an amount of resources required to support a market that consumes a volume of the image detection system including the NIR VC-SEL devices, the NIR light photodiode devices, and the VIS photodiode devices (e.g. semiconductor manufacturing tools, labor, raw materials, and/or computing resources) is reduced.

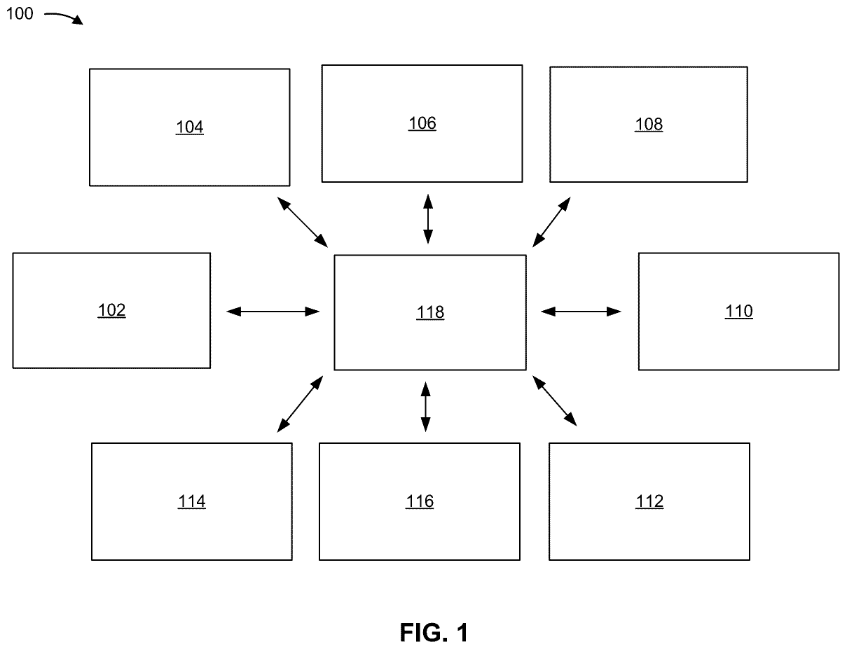

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, an ion implantation tool 114, a bonding/debonding tool 116, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The bonding/debonding tool 116 is a semiconductor processing tool that is capable of joining two or more semiconductor substrates, or two or more semiconductor devices, together. For example, the bonding/debonding tool 116 may include a eutectic bonding tool that is capable of forming eutectic bond between two or more wafers together. In these examples, the bonding/debonding tool 116 may heat the two or more wafers to form a eutectic system between the materials of the two or more wafers. As another example, the bonding/debonding tool 116 may include a hybrid bonding tool, a direct bonding tool, and/or another type of bonding tool. In some implementations, the bonding/debonding tool 116 may heat the two or more wafers to separate the two or more wafers.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

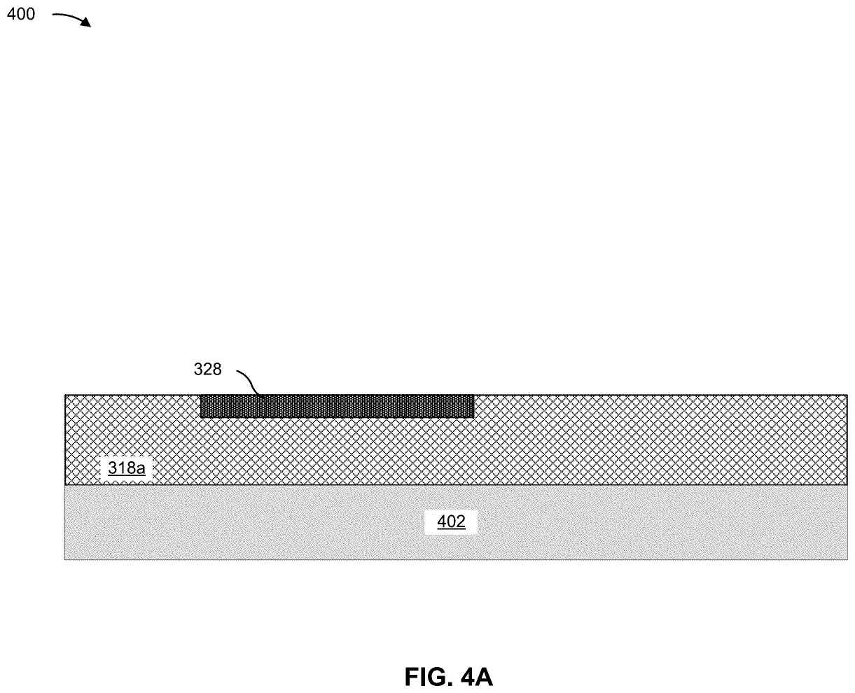

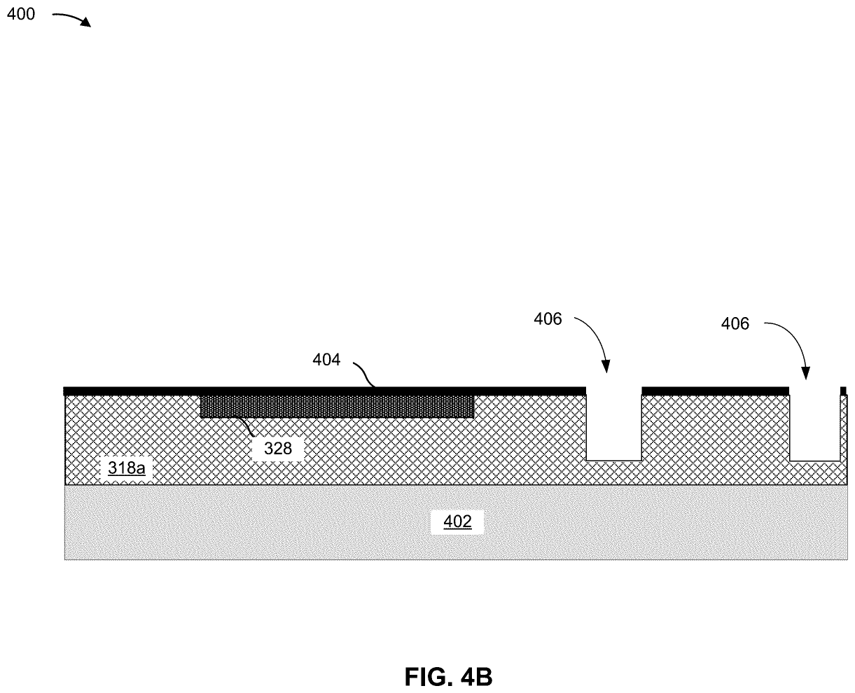

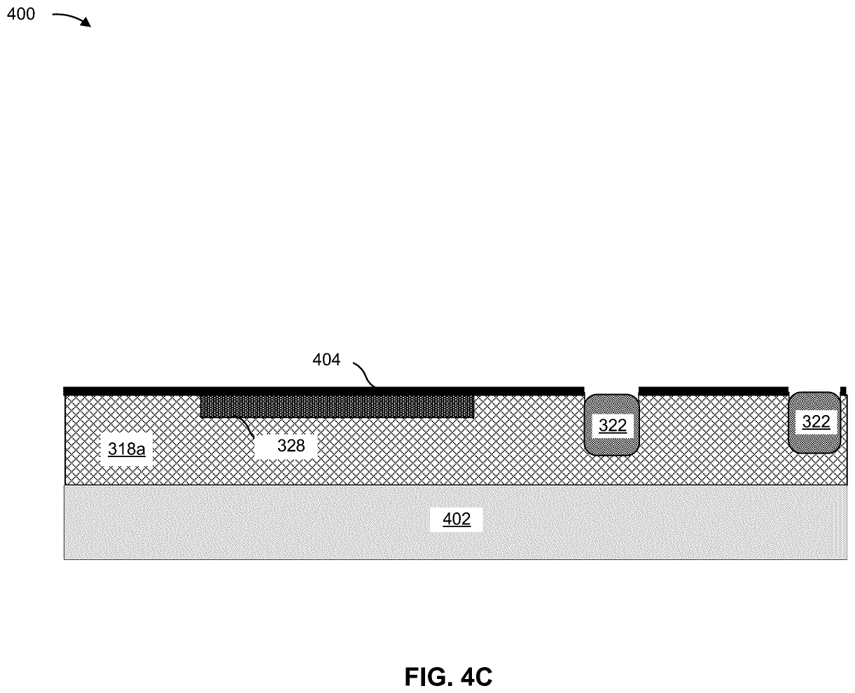

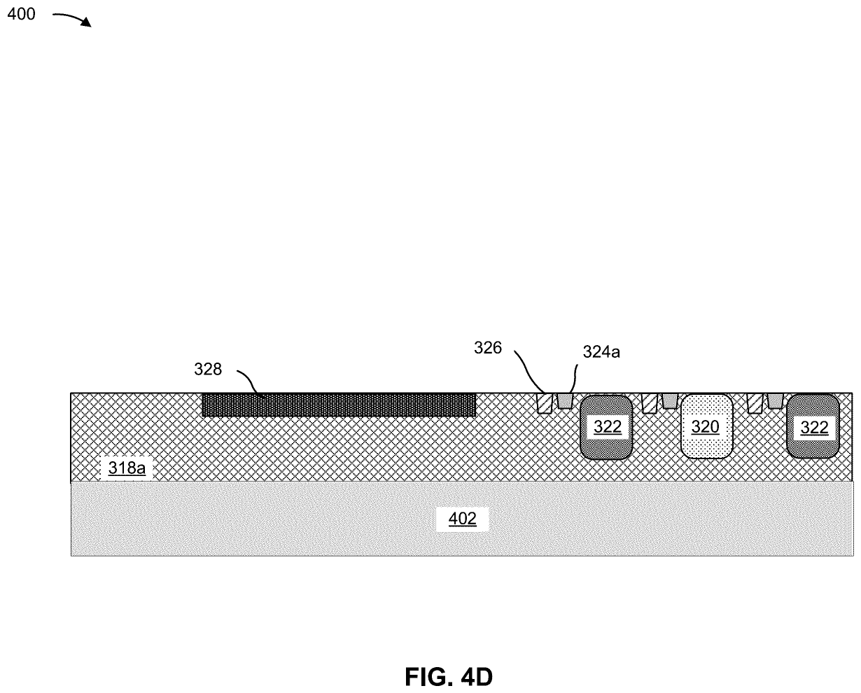

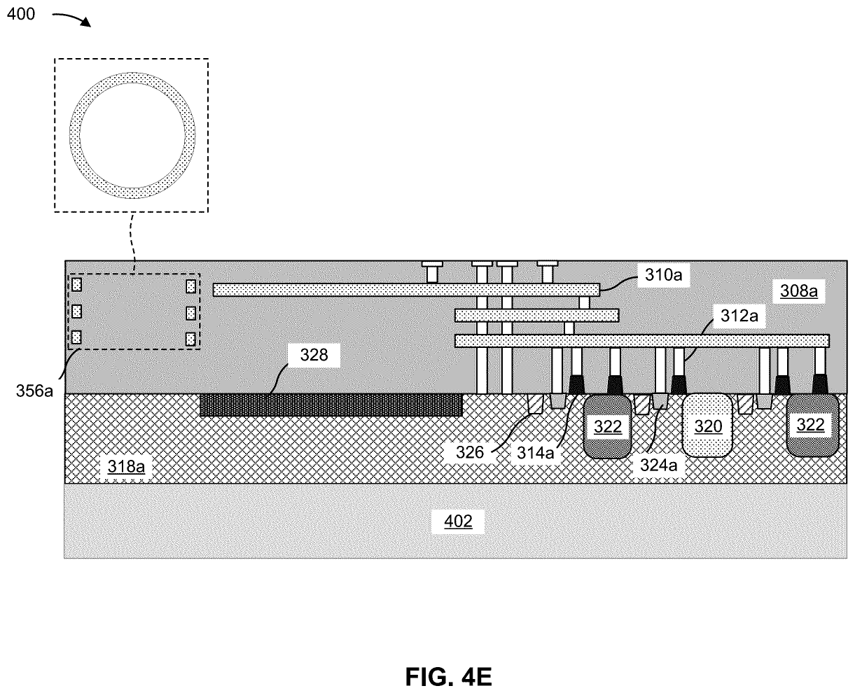

One or more of the semiconductor processing tools 102-116 and/or the wafer/die transport tool 118 may perform a series of one or more semiconductor processing operations described herein. The series of one or more semiconductor processing operations includes forming an NIR light photodiode (e.g., a near infrared light photodiode) in a first semiconductor layer, where the NIR light photodiode includes a first type III or type V material. The series of one or more semiconductor processing operations includes forming a first dielectric region that joins with the first semiconductor layer and that includes a first ring-shaped etch block structure. The series of one or more semiconductor processing operations includes forming a structure including an NIR light emitting laser diode (e.g., a near infrared light emitting laser diode) in a second semiconductor layer, where the NIR light emitting laser diode includes a second type III or type V material. The series of one or more semiconductor processing operations includes forming a second dielectric region that joins with the second semiconductor layer and that includes a second ring-shaped etch block structure, where the second ring-shaped etch block structure is above the structure including the NIR light emitting laser diode. The series of one or more semiconductor processing operations includes joining the first dielectric region and the second dielectric region to co-axially align the first ring-shaped etch block structure with the second ring-shaped etch block structure above the second ring-shaped etch block structure. The series of one or more semiconductor processing operations includes forming a cavity through a center of the first ring-shaped etch block structure, through a center of the second ring-shaped etch block structure, and to the structure including the NIR light emitting laser diode. In some implementations, one or more of the semiconductor processing operations performed by the semiconductor processing tools 102-116 and/or the wafer/die transport tool 118 may correspond to one or more semiconductor processing operations described in connection with FIGS. 4A-4E, 5A-5G, 6A-6I, and elsewhere herein, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

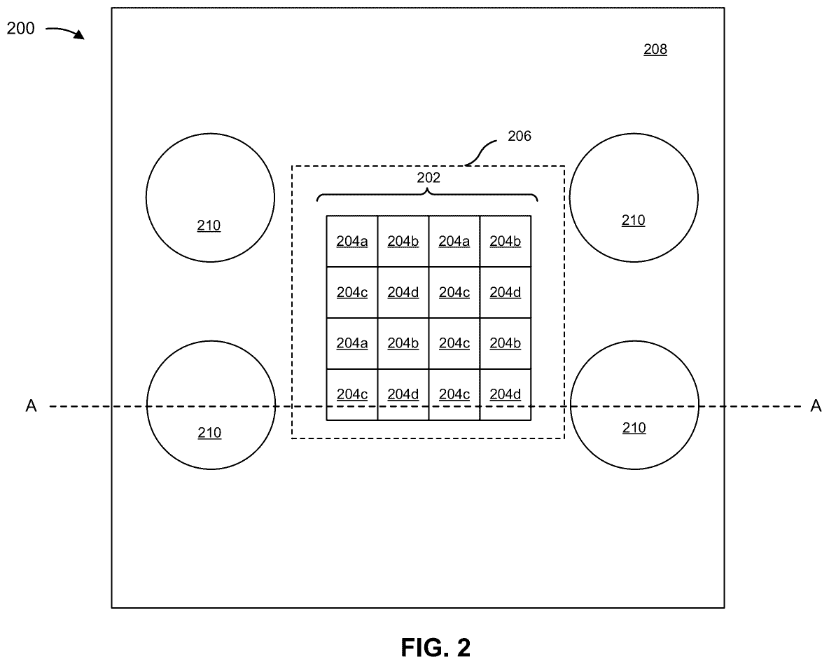

FIG. 2 is a diagram of a portion of an example optoelectronic device 200 described herein. The optoelectronic device 200 may be configured to be deployed in various implementations, such as digital cameras, video recorders, night-vision cameras, automotive sensors and cameras, and/or other types of low-light implementations.

As shown in the top-down view of FIG. 2, the optoelectronic device 200 includes a pixel sensor array 202. As shown in FIG. 2, the pixel sensor array 202 includes pixel sensors 204a-204d. As further shown in FIG. 2, the pixel sensors 204a-204d are arranged in a grid. In some implementations, the pixel sensors 204a-204d are square-shaped (as shown in the example in FIG. 2). In some implementations, the pixel sensors 204a-204d include other shapes such as circle shapes, octagon shapes, diamond shapes, and/or other shapes.

In some implementations, the pixel sensor array 202 includes a filter array that causes the pixels sensors 204a-204d to sense and/or accumulate incident light (e.g., light directed toward the pixel sensor array 202) of particular wavelengths. For example, the pixel sensor 204a may include a color filter that limits the pixel sensor 204a to absorbing and accumulating photons of incident light corresponding to blue visible light (e.g., electromagnetic waves having a wavelength in a range of approximately 450 nanometers to approximately 490 nanometers). Additionally, or alternatively, the pixel sensor 204b may include a color filter that limits the pixel sensor 204b to absorbing and accumulating photons of incident light corresponding to green visible light (e.g., electromagnetic waves having a wavelength in a range of approximately 490 nanometers to approximately 570 nanometers). Additionally, or alternatively, the pixel sensor 204c may include a color filter that limits the pixel sensor 204c to absorbing and accumulating photons of incident light corresponding to red visible light (e.g., electromagnetic waves having a wavelength in a range of approximately 620 nanometers to approximately 750 nanometers). Additionally, or alternatively, the pixel sensor 204d may include a filter that limits the pixel sensor 204d to absorbing and accumulating photons of incident light corresponding to NIR light (e.g., electromagnetic waves having a wavelength in a range of approximately 700 nanometers to approximately 2500 nanometers). Photodiodes for each pixel sensor 204a-204d of the pixel sensor array 202 generate an electrical charge representing the intensity or brightness of the incident light (e.g., a greater amount of charge may correspond to a greater intensity or brightness, and a lower amount of charge may correspond to a lower intensity or brightness).

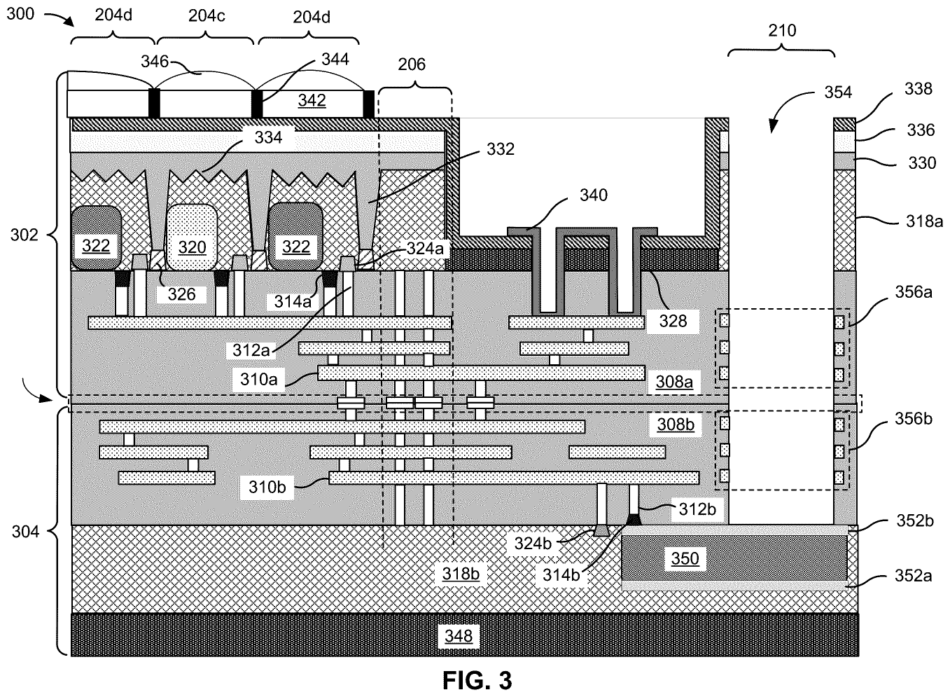

As further shown in FIG. 2, the optoelectronic device 200 includes a seal ring structure 206 that surrounds the pixel sensor array 202 and a peripheral region 208 that includes one or more NIR light emitting structure(s) 210 (e.g., near infrared light emitting structures). The seal ring structure 206 provides for a physical barrier that substantially eliminates moisture and/or cracking from penetrating the optoelectronic device 200. Furthermore, and as described in greater detail in connection with FIG. 3 and elsewhere herein, the seal ring structure 206 may include a combination of interconnect structures, metallization layers, and/or deep trench isolation structures that prevent a direct transmission of NIR light from the NIR light emitting structures 210 to one or more photodiodes of the pixel sensors 204a-204d.

As indicated above, FIG. 2 is provided as an example. Other examples may differ from what is described with regard to FIG. 2.

FIG. 3 is a diagram of an example optoelectronic device 300 described herein. As shown in FIG. 3 (e.g., a section view), the optoelectronic device 300 includes a semiconductor device 302 (e.g., a first semiconductor device) and a semiconductor device 304 (e.g., a second semiconductor device) below the semiconductor device 302. The semiconductor device 302 and the semiconductor device 304 are joined at an interface region 306. In some implementations, the interface region 306 includes material layers that are joined through a eutectic bonding process. For example, within the interface region 306 the semiconductor devices 302 and 304 may each include respective passivation layers (layers of an aluminum dioxide material (Al₂O₃), among other examples) that are joined with one another.

In addition to the pixel sensors 204c, the pixel sensors 204d, and the seal ring structure 206, the semiconductor device 302 includes various layers and/or structures. For example, the semiconductor device 302 includes a dielectric region 308a. The dielectric region 308a (e.g., an intermetal dielectric region) may include one or more layers of dielectric material (e.g., a silicon oxide (SiOₓ), a silicon nitride (SixNy), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material). Various metallization layers 310a and interconnect structures 312a (e.g., vertical interconnect access structures, or vias) may be formed in and/or in between the layers of the dielectric region 308a. The metallization layers 310a and/or interconnect structures 312a (e.g., vertical interconnect access structures, or vias) may include bonding pads, conductive lines, and/or other types of conductive structures that electrically connect the various regions of the optoelectronic device 300 and/or electrically connect the various regions of the optoelectronic device 300 to one or more external devices and/or external packaging. The interconnect structures 312a and metallization layers 310a may be referred to as a BEOL metallization stack, and may include a conductive material, such as gold, copper, silver, cobalt, tungsten, a metal alloy, or a combination thereof, among other examples.

In some implementations, portions of transistor circuitry are included in the dielectric region 308a. For example, and as shown in FIG. 3, the dielectric region 308a may include gate structures 314a. The gate structures 314a may include a semiconductive material such as a polysilicon material, a conductive material such as one or more metallic materials, and/or one or more other materials, among other examples.

The optoelectronic device 300 further includes a substrate layer 318a. The substrate layer 318a may include a semiconductor material such as silicon, a III-V compound such as gallium arsenide (GaAs), a silicon on insulator (SOI) layer, and/or another type of substrate that is capable of generating a charge from photons of incident light.

Photodiodes for the pixel sensor array 202 are included within the substrate layer 318a. For example, photodiode 320 for sensing visible light may include regions of the substrate layer 318a that are doped with a plurality of types of ions to form a p-n junction or a p-i-n junction (e.g., a junction between a p-type portion, an intrinsic (or undoped) type portion, and an n-type portion). In some implementations, the substrate layer 318a is doped with an n-type dopant to form a first portion (e.g., an n-type portion) of a photodiodes 320 and a p-type dopant to form a second portion (e.g., a p-type portion) of the photodiodes 320.

Additionally, the substrate layer 318a includes photodiodes 322 for sensing NIR light. The photodiodes 322 may include a material that is a type III periodic element and/or a type V periodic element. Based on properties of the material (e.g., the type III periodic element material and/or the type V periodic element material), the photodiodes 322 may absorb photons with higher energies and/or longer wavelengths, including those in the infrared region and/or NIR region of the electromagnetic wavelength spectrum, to significantly enhance a quantum efficiency of the photodiodes 322 for NIR light absorption relative to the photodiodes 320 (which have a high quantum efficiency for absorbing visible light). Examples of the material(s), which may be epitaxially grown within cavities in the substrate layer 318a to selectively form the photodiodes 322, include a germanium material (Ge), a silicon germanium material (SiGe), a gallium arsenide material (GaAs), and an indium phosphide material (InP).

In some implementations, the substrate layer 318a includes portions of transistor structures. For example, the substrate layer 318a may include source/drain regions 324a. The source/drain regions 324a may include a semiconductive material such as a polysilicon material, a crystalline silicon material, and/or another semiconductive material, among other examples. In some implementations, the transistor structures including the gate structures 314a and the source/drain regions 324a are associated with the photodiodes 320 and/or the photodiodes 322.

As shown in FIG. 3, shallow trench isolation (STI) regions 326 may be included in the substrate layer 318a between the photodiodes 320 and the photodiodes 322. The STI regions 326 may include an insulative material such as a silicon dioxide (SiO₂) material, among other examples. The STI regions 326 may electrically isolate respective transistor structures formed by the gate structures 314a and the source/drain regions 324a, and/or may provide optical isolation for the photodiodes 320 and 322.

Further, and in some implementations, a shallow trench isolation (STI) region 328 is above the dielectric region 308a. The STI region 328 may optically and/or electrically isolate the pixel sensors 204 from other regions of the optoelectronic device 300.

As shown in FIG. 3, an oxide layer 330 is located above the substrate layer 318a. The oxide layer 330 may function as a passivation layer between the substrate layer 318a and the upper layers of the pixel sensors 204. In some implementations, the oxide layer 330 includes an oxide material such as a silicon oxide (SiOₓ). In some implementations, a silicon nitride (SiNₓ), a silicon carbide (SiCₓ), or a mixture thereof, such as a silicon carbon nitride (SiCN), a silicon oxynitride (SiON), or another dielectric material is used in place of the oxide layer 330 as a passivation layer.

Deep trench isolation (DTI) structures 332 may be included in the substrate layer 318a and may include portions of the oxide layer 330. In particular, the DTI structures 332 may be formed between each of the photodiode(s) 320 and 322. The DTI structures 332 may form a grid layout in which the DTI structures 332 extend laterally across the pixel sensor array 202 and intersect at various locations of the pixel sensor array 202. The DTI structures 332 extend downward into the substrate layer 318a adjacent to the photodiode(s) 320 and 322. The DTI structures 332 may provide optical isolation between the pixel sensors 204 of the pixel sensor array 202 to reduce the amount of optical crosstalk between adjacent pixel sensors 204. In particular, DTI structures 332 may absorb, refract, and/or reflect incident light, which may reduce the amount of incident light that travels through a pixel sensor 204 into an adjacent pixel sensor 204 and is absorbed by the adjacent pixel sensor 204. In some implementations, the DTI structures 332 are included as part of the seal ring structure 206.

As shown in FIG. 3, HA regions 334 are located above the photodiodes 320 and/or 322. Each HA region 334 may be defined by a shallow trench. A plurality of adjacent HA regions 334 may form a periodic or zig-zag structure in the substrate layer 318a and/or the photodiode(s) 320 and/or 322. The HA regions 334 may be formed in a same side of the substrate layer 318a as the DTI structures 332.

The HA regions 334 may increase the absorption of incident light for a pixel sensor 204 (thereby increasing the quantum efficiency of the pixel sensor array 202) by modifying or changing the orientation of the refractive interface between the photodiodes 320 and 322 and the substrate layer 318a. The angled walls of the HA regions 334 change the orientation of the interface between the photodiodes 320 and 322 and the substrate layer 318a by causing the interface to be diagonal relative to the orientation of a top surface of the substrate layer 318a. This change in orientation may result in a smaller angle of refraction relative to a flat surface of the top surface of the substrate layer 318a for the same angle of incidence of incident light. As a result, the HA regions 334 are capable of directing wider angles of incident light toward the center of the photodiodes 320 and 322 than if no HA regions 334 were included in the optoelectronic device 300.

In some implementations, a top surface of the substrate layer 318a, the surfaces of the DTI structures 332, and the surfaces of the HA regions 334 are coated with an antireflective coating (ARC) layer to decrease reflection of incident light away from the photodiodes 320 and 322 to increase transmission of incident light into the substrate layer 318a and the photodiodes 320 and 322.

As further shown in FIG. 3, one or more oxide layers (e.g., passivation layers) are formed above and/or on the oxide layer 330. For example, an oxide layer 336 (e.g., a backside illumination or BSI layer) may be located above and/or on portions of the oxide layer 330. As another example, a oxide layer 338 (e.g., a buffer oxide layer) may be located above and/or on the oxide layer 336. In some implementations, the oxide layer 336 and/or the oxide layer 338 include an oxide material such as a silicon oxide (SiOₓ). In some implementations, a silicon nitride (SiNₓ), a silicon carbide (SiCₓ), or a mixture thereof, such as a silicon carbon nitride (SiCN), a silicon oxynitride (SiON), or another dielectric material is used in place of the oxide layer 336 and/or the oxide layer 338 as a passivation layer.

A bonding pad 340 may be located above the STI region 328, and/or above and/or on the oxide layer 338. The bonding pad 340 may extend through the oxide layer 338, through the STI region 328, and to the dielectric region 308a, and may contact one or more metallization layers 310a in the dielectric region 308a. The bonding pad 340 may include a conductive material, such as gold, silver, aluminum, copper, aluminum-copper, titanium, tantalum, titanium nitride, tantalum nitride, tungsten, a metal alloy, other metals, or a combination thereof. As shown in FIG. 3, the bonding pad 340 may connect with one of the metallization layers 310a (e.g., an Ml metallization layer) of the optoelectronic device 300 to provide an electrical connection between the metallization layer and external devices and/or external packaging.

As shown in FIG. 3, the semiconductor device 304 includes one or more features similar to those described in connection with semiconductor device 302 (e.g., features including similar arrangement, function, and/or materials). For example, the semiconductor device 304 includes dielectric region 308b, metallization layers 310b, interconnect structures 312b, gate structures 314b, substrate layer 318b, and/or source/drain regions 324b.

In some implementations, the optoelectronic device 300 includes a filter layer 342, a grid structure 344, and/or a micro-lens layer 346. As an example, the filter layer 342 may include an array of polycarbonate, polyimide, or acrylic material regions that allow visible light waves (e.g., red, green, or blue light waves) to pass through to the photodiodes 320 and NIR light waves to pass through to the photodiodes 322. The grid structure 344 may include columns formed from a metal material (e.g., an aluminum material (Al), a tungsten (W) material, and/or a copper material (Cu), among other examples) that reduce or prevent cross-talk of photons (e.g., optical cross-talk) between adjacent pixel sensors 204. The micro-lens layer 346 may include a plurality of micro-lenses formed from a polymer material that focus and/or converge light through pixel sensors in a pixel sensor array (e.g., each of the pixel sensors 204 included in the pixel sensor array 202).

As shown in FIG. 3, the semiconductor device 304 includes a buffer layer 348. The buffer layer 348 may include a dielectric material such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. The buffer layer 348 may serve as a layer by which the semiconductor device 304 is bonded to the carrier substrate so that back side processing may be performed on the optoelectronic device 300.

As shown in FIG. 3, the semiconductor device 304 further includes a light emitting laser diode 350. The light emitting laser diode 350 (e.g., an NIR light emitting laser diode) may include a quantum well structure that includes a type III periodic element or a type V periodic element. Examples of the material, which may be epitaxially grown within cavities in the substrate layer 318b to selectively form the light emitting laser diode 350, include a germanium material (Ge), a silicon germanium material (SiGe), a gallium arsenide material (GaAs), and an indium phosphide material (InP).

In some implementations, a material included in the light emitting laser diode 350 and the photodiodes 322 is a same selectively grown epitaxial material. In some implementations, materials included in the light emitting laser diode 350 and the photodiodes 322 are different selectively grown epitaxial materials.

As further shown in FIG. 3, a distributed Bragg reflection structure 352a (also known as a Bragg mirror or Bragg grating) may be below the light emitting laser diode 350. Additionally, or alternatively, a distributed Bragg reflection structure 352b may be above the light emitting laser diode 350.

The distributed Bragg reflection structure 352a and/or the distributed Bragg reflection structure 352b include alternating layers or regions of materials with different refractive indices. Such materials may include a dielectric material such as a silicon dioxide material (SiO₂), a semiconductor material such as a silicon material (Si), or a conductive material such as an aluminum material (Al), among other examples.

By precisely controlling the thicknesses and refractive indices of the alternating layers, the distributed Bragg reflection structures 352a and/or 352b selectively reflect a particular wavelength or a narrow range of wavelengths, while allowing the transmission of other wavelengths. This reflection is based on the principle of Bragg's law, which describes the constructive interference of waves reflected from a periodic structure.

As further shown in FIG. 3, a transmission region 354 (e.g., a near infrared light transmission region) is included in the optoelectronic device 300 above the light emitting laser diode 350. The transmission region 354 penetrates through portions of the semiconductor devices 302 and 304 to the distributed Bragg reflection structure 356b. In some implementations the transmission region 354 corresponds to a region filled with a solid substance that is transmissive to NIR light (an aluminum oxide solid substance (Al₂O₃) or a high-purity silicon dioxide solid substance (SiO₂), among other examples). In some implementations, the transmission region 354 corresponds to a region filled with a gaseous mixture that is transmissive to NIR light (e.g., air). In some implementations, the transmission region 354 corresponds to a region filled with a liquid mixture (e.g., water).

In some implementations, the transmission region 354 passes through centers of ring-shaped etch block structures that are designed to maintain a shape of the transmission region 354 during formation of the transmission region 354. For example, and as shown in FIG. 3, the semiconductor device 302 includes a ring-shaped etch block structure 356a (e.g., a first ring-shaped etch block structure formed from portions of the metallization layers 310a), and the semiconductor device 304 includes a ring-shaped etch block structure 356b (e.g., a second ring-shaped etch block structure formed from portions of metallization layers 310b).

As shown in FIG. 3, the transmission region 354 is disposed through centers of the ring-shaped block structures 352a and 352b, where the ring-shaped block structures 352a and 352b are co-axially aligned. Furthermore, the transmission region 354 intersects with the distributed Bragg reflection structure 352b.

The optoelectronic device 300 (e.g., a three-dimensional, complementary metal-oxide image sensor (3D-CIS) device) may include combinations of one or more different types of semiconductor devices. For example, the semiconductor device 302 may correspond to a system-on-chip (SoC) type of semiconductor device. Additionally, or alternatively, the semiconductor device 304 may correspond to an application-specific integrated circuit (ASIC) type of semiconductor device that is joined with a vertical-cavity surface emitting laser (VC-SEL) type of semiconductor device.

The number and arrangement of components, structures, and/or layers shown in the optoelectronic device 300 of FIG. 3 are provided as an example. In practice, the optoelectronic device 300 may include additional components, structures, and/or layers; fewer components, structures, and/or layers; different components, structures, and/or layers; and/or differently arranged components, structures, and/or layers than those shown in FIG. 3.

As described in connection with FIGS. 2 and 3, and in an example implementation, an optoelectronic device (e.g., the optoelectronic device 300) includes a first semiconductor device (e.g., the semiconductor device 302) including a first layer of a first semiconductor material (e.g., the substrate layer 318a) and an array of pixel structures (e.g., the pixel sensors 204a-204d). The pixel structures include an array of visible light photodiodes (e.g., the photodiodes 320) within the first layer of the first semiconductor material and an array of NIR light photodiodes (e.g., the photodiodes 322) including a first epitaxial material and within the first layer of the first semiconductor material. In some implementations, the array of NIR light photodiodes is interspersed amongst the array of visible light photodiodes. The optoelectronic device includes a second semiconductor device (e.g., the semiconductor device 304) joined with the first semiconductor device, below the first semiconductor device, that includes a second layer of a second semiconductor material (e.g., the substrate layer 318b) and a portion of an NIR light emitting structure (e.g., a portion of the NIR light emitting structure 210). The NIR light emitting structure includes an NIR light emitting laser diode (e.g., the NIR light emitting diode 350) within the second semiconductor material that includes a second epitaxial material.

In another example implementation, an optoelectronic device (e.g., the optoelectronic device 300) includes a first layer of a first semiconductor (e.g., the substrate layer 318a) including an NIR light photodiode (e.g., the photodiodes 322) that includes a first epitaxial material. The optoelectronic device includes a first dielectric region (e.g., the dielectric region 308a) below the NIR light photodiode and adjacent to the NIR light photodiode. The first dielectric region includes a first ring-shaped etch block structure. (e.g., the ring-shaped etch block structure 356a). The optoelectronic device includes a second dielectric region (e.g., the dielectric region 308b) below the first dielectric region. The second dielectric region includes a second ring-shaped etch block structure (e.g., the ring-shaped etch block structure 356b) that is co-axially aligned with the first ring-shaped etch block structure. The optoelectronic device includes a second layer of a second semiconductor material (e.g., the substrate layer 318b) below the second dielectric region. The second layer of the second semiconductor material includes an NIR light emitting laser diode (e.g., the light emitting laser diode 350) that includes a second epitaxial material. The optoelectronic device includes an NIR light transmission region (e.g., the transmission region 354) disposed through a center of the first ring-shaped etch block structure, through a center of the second ring-shaped etch block structure, and to a structure including the NIR light emitting laser diode.

In this way, a performance (e.g., a QE) of the optoelectronic device 300 including the light emitting laser diode 350 and the transmission region 354 (an NIR VC-SEL device), the pixel sensors 204d (e.g., NIR pixel sensors), and the pixel sensors 204a-204c (e.g., VIS pixel sensors) is improved relative to another optoelectronic device including doped, silicon-based photodiode devices and/or LED devices. Improving the performance of the optoelectronic device increases a manufacturing yield, of the optoelectronic device, to a particular performance threshold. Additionally, combining the light emitting laser diode 350, the pixel sensors 204d, and the pixel sensors 204a-204c into a single device (e.g., a 3D-CIS device) reduces an overall device space (e.g., silicon) and/or image detection system space. By increasing the manufacturing yield and consuming less device space and/or image detection system space, an amount of resources (e.g. semiconductor manufacturing tools, labor, raw materials, and/or computing resources) required to support a market that consumes a volume of the image detection system including the light emitting laser diode 350 (e.g., an NIR light emitting diode), the pixel sensors 204d (e.g., NIR light pixel sensors), and/or the pixel sensors 204a-204c (e.g., VIS light pixel sensors) is reduced.

FIGS. 4A-4E are diagrams of an example implementation 400 for forming portions of an optoelectronic device including NIR light photodiodes. Portions of the optoelectronic device may correspond to portions of the optoelectronic device 300 as described in connection with FIG. 3 and elsewhere herein. As part of the implementation 400, a series of operations may be performed by one or more of the semiconductor processing tools 102-116 and/or the wafer/die transport tool 118 described in connection with FIG. 1.

As shown in FIG. 4A, a carrier structure 402 (a glass carrier structure or a silicon carrier structure, among other examples) holds the substrate layer 318a. The deposition tool 102 may deposit the substrate layer 318a in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the substrate layer 318a after the deposition tool 102 deposits the substrate layer 318a.

As part of the series of operations, the STI region 328 is formed in the substrate layer 318a. As an example, the deposition tool 102, the exposure tool 104, the developer tool 106, and/or the etch tool 108 may perform a combination of photolithography, etching, and deposition operations to form the STI region 328 in the substrate layer 318a.

As shown in FIG. 4B, and as part of the series of operations, a masking layer 404 is formed and patterned over the substrate layer 318a. For example, and as part of forming the masking layer 404, the deposition tool 102 may deposit a layer of a silicon nitride (SiN) material in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the masking layer 404 after the deposition tool 102 deposits the masking layer 404. Furthermore, as part of patterning the masking layer 404, the exposure tool 104, the developer tool 106, and/or the etch tool 108 may perform a combination of photolithography and etching, operations to form the pattern.

As further shown in FIG. 4B, cavities 406 are formed in the substrate layer 318a. To form the cavities 406, the pattern in the masking layer 404 is used. The etch tool 108 etches the substrate layer 318a based on the pattern to form the cavities 406 in the substrate layer 318a. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique).

Turning to FIG. 4C, the photodiodes 322 are formed in the cavities 406. The deposition tool 102 may deposit the photodiodes 322 in an epitaxy operation (e.g., a selective epitaxial growth operation), a deposition operation described in connection with FIG. 1, and/or another suitable deposition operation. In some implementations, the planarization tool 110 planarizes the photodiodes 322 after the deposition tool 102 deposits the photodiodes 322. Additionally, or alternatively, the planarization tool 110 may remove the masking layer 404 after the deposition tool 102 deposits the photodiodes 322.

As shown in FIG. 4D, and as part of the series of operations, the photodiodes 320 are formed in the substrate layer 318a. As an example, the deposition tool 102, the exposure tool 104, the developer tool 106, the etch tool 108, and/or the ion implantation tool 114 may perform a combination of deposition, photolithography, etching, and/or implant operations to implant ions in a defined region below the surface of the substrate to form the photodiodes 320.

Additionally, and as shown in FIG. 4D, the source/drain regions 324a may be formed in the substrate layer 318a. As an example, the deposition tool 102, the exposure tool 104, the developer tool 106, the etch tool 108, and/or the ion implantation tool 114 may perform a combination of deposition, photolithography, etching, and/or implant operations to form the source/drain regions 324a.

Additionally, and as shown in FIG. 4D, the STI regions 326 may be formed in the substrate layer 318a. As an example, the deposition tool 102, the exposure tool 104, the developer tool 106, and/or the etch tool 108, may perform a combination of deposition, photolithography, and/or etching operations to form the STI regions 326.

As shown in FIG. 4E, the dielectric region 308a is formed above and/or on the substrate layer 318a. As part of forming the dielectric region 308a, and as an example, the deposition tool 102 may deposit one or more dielectric layers of the dielectric region 308a using a CVD operation, a PVD operation, an ALD operation, another deposition operation described above in connection with FIG. 1, and/or another suitable deposition operation. In some implementations, the planarization tool 110 planarizes the one or more of the dielectric layers after the deposition tool 102 deposits the dielectric layers.

Additionally, of alternatively and as part of forming the dielectric region 308a, the gate structures 314a may be formed on the substrate layer 318a. As an example, the deposition tool 102, the exposure tool 104, the developer tool 106, and/or the etch tool 108, may perform a combination of deposition, photolithography, and/or etching operations to form the gate structures 314a.

Additionally, or alternatively and as part of forming the dielectric region 308a, the deposition tool 102, the exposure tool 104, the developer tool 106, and/or the etch tool 108 may perform a combination of deposition, photolithography, and/or etching operations to form the interconnect structures 312a. The deposition tool 102 or the plating tool 112 may further form one or more of the metallization layers 310a. To form one or more of the metallization layers 310a, the deposition tool 102 and/or the plating tool 112 may deposit one or more of the metallization layers 310a in a CVD operation, a PVD operation, an ALD operation, an electroplating operation, another deposition operation described above in connection with FIG. 1, and/or another suitable deposition operation. In some implementations, the planarization tool 110 planarizes one or more of the metallization layers 310a after deposition.

In some implementations, the deposition tool 102, the exposure tool 104, the developer tool 106, and/or the etch tool 108 perform a combination of deposition, photolithography, and/or etching operations to form the ring-shaped etch block structure 356a from portions of the metallization layers 310a. Although a pattern of the ring-shaped etch block structure 356a is shown as round in the detailed view (e.g., a top view) of FIG. 4E, the ring-shaped etch block structure 356a may be square, rectangular, elliptical, or another shape that may be suitable to aid in formation of a transmission region (e.g., the transmission region 354).

As indicated above, FIGS. 4A-4E are provided as an example. Other examples may differ from what is described with regard to FIGS. 4A-4E.

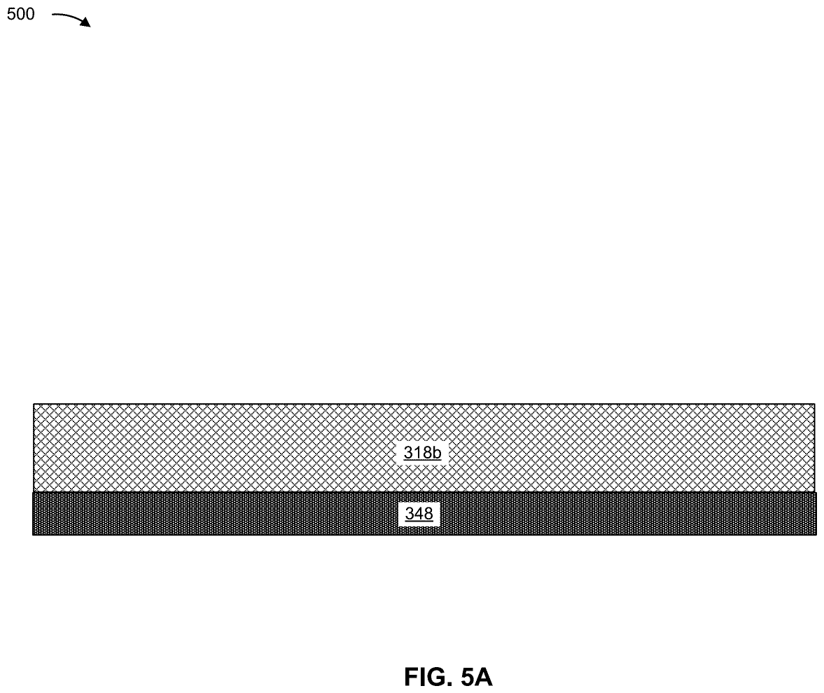

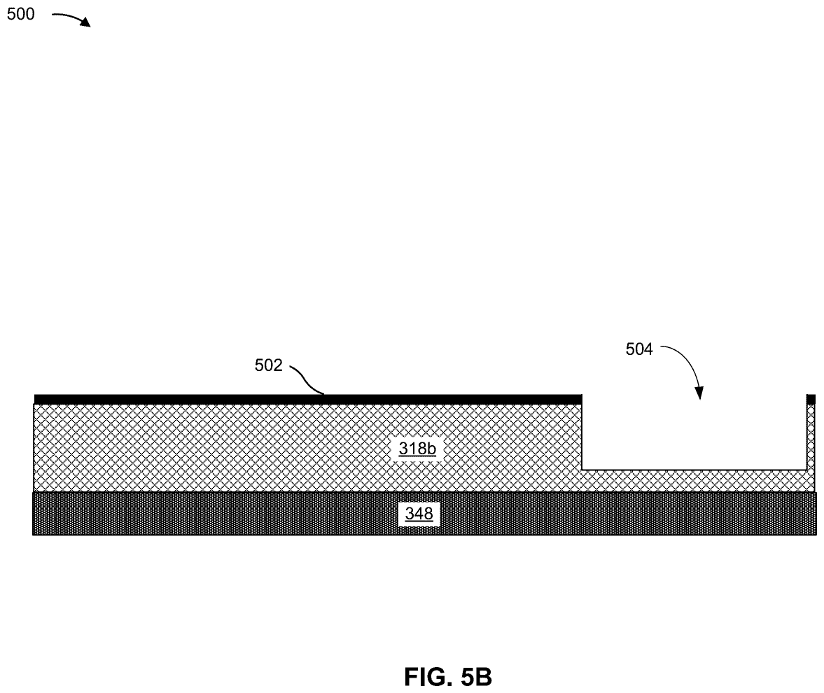

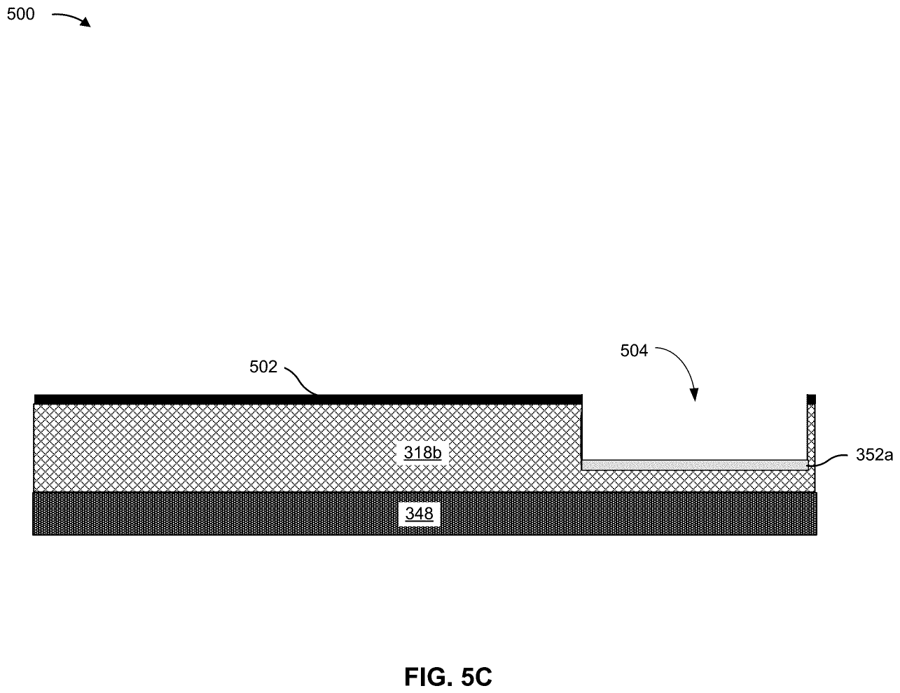

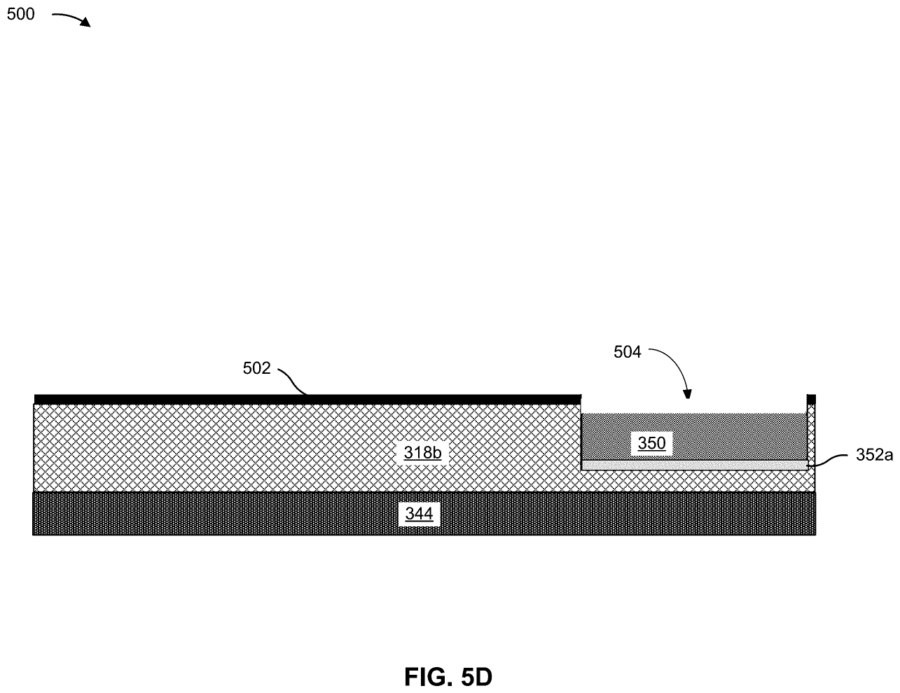

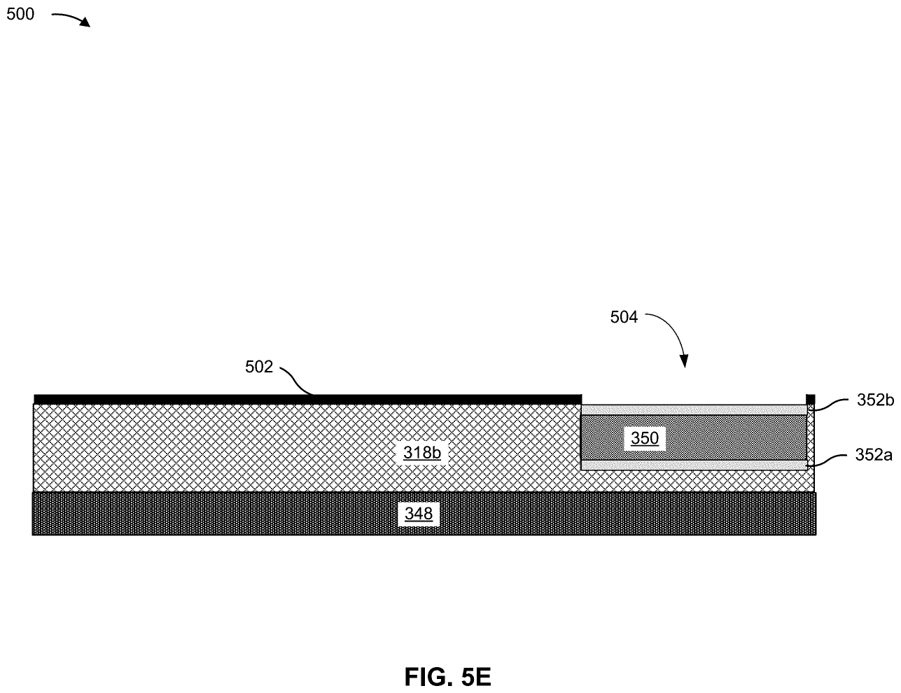

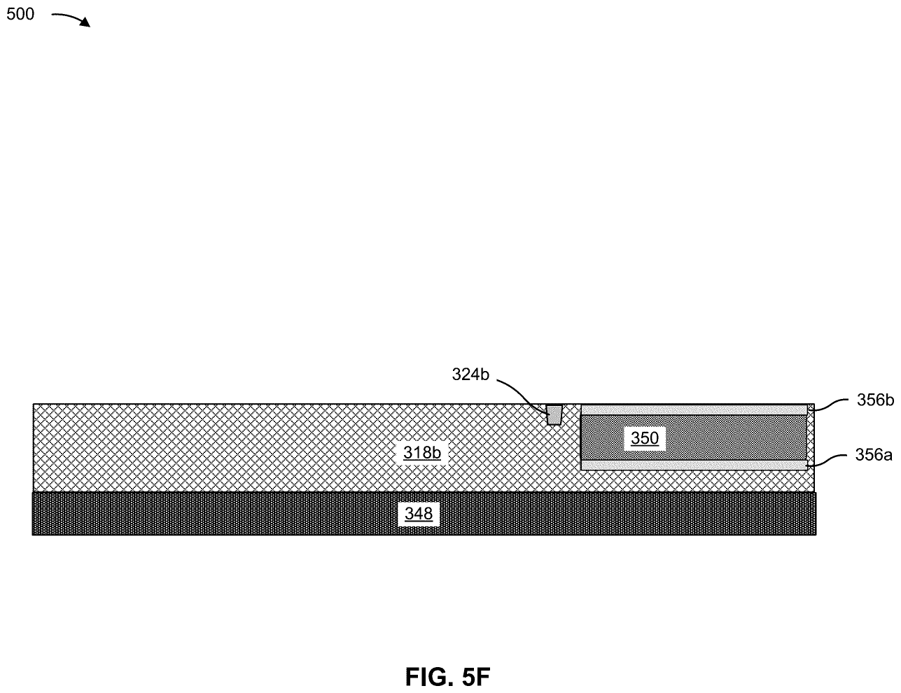

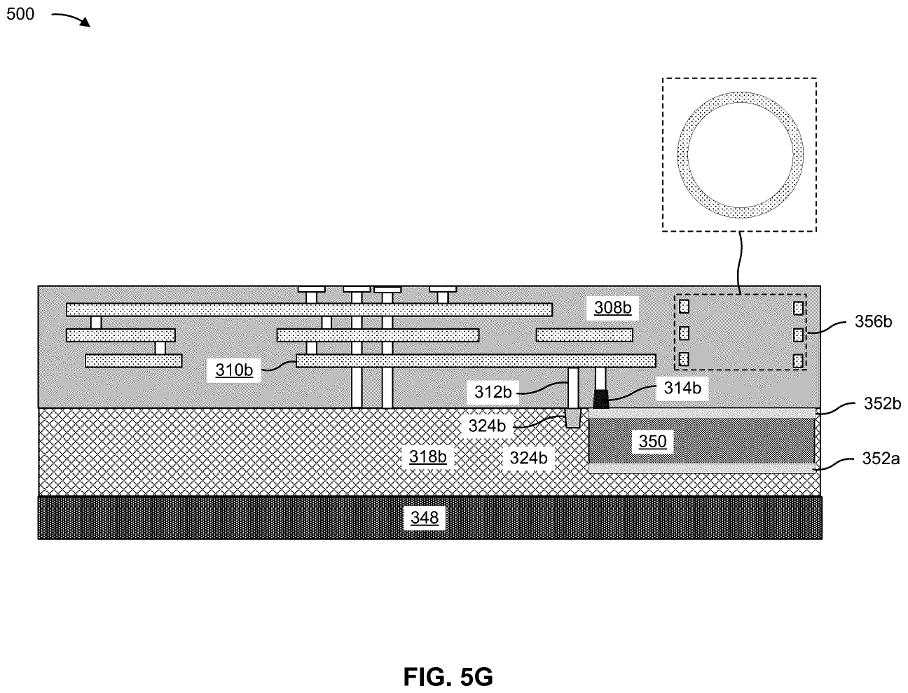

FIGS. 5A-5G are diagrams of an example implementation 500 for forming portions of an optoelectronic device including an NIR light emitting laser diode. Portions of the optoelectronic device may correspond to portions of the optoelectronic device 300 as described in connection with FIG. 3 and elsewhere herein. As part of the implementation 500, a series of operations may be performed by one or more of the semiconductor processing tools 102-116 and/or the wafer/die transport tool 118 described in connection with FIG. 1.

As shown in FIG. 5A, the buffer layer 348 holds the substrate layer 318b. The deposition tool 102 may deposit the substrate layer 318a in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the substrate layer 318a after the deposition tool 102 deposits the substrate layer 318b.

As shown in FIG. 5B, and as part of the series of operations, a masking layer 502 is formed and patterned over the substrate layer 318a. For example, and as part of forming the masking layer 502, the deposition tool 102 may deposit a layer of a silicon nitride (SiN) material in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the masking layer 502 after the deposition tool 102 deposits the masking layer 502. Furthermore, as part of patterning the masking layer 502, the exposure tool 104, the developer tool 106, and/or the etch tool 108 may perform a combination of photolithography and etching, operations to form the pattern.

As further shown in FIG. 5B, a cavity 504 is formed in the substrate layer 318b. To form the cavity 504, the pattern in the masking layer 502 is used. The etch tool 108 etches the substrate layer 318b based on the pattern to form the cavity 504 in the substrate layer 318b. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique).

Turning to FIG. 5C, the distributed Bragg reflection structure 352a is formed in the cavity 504. Forming the distributed Bragg reflection structure 352a may include the deposition tool 102 depositing layers of the distributed Bragg reflection structure 352a using one or more of a PVD operation, an ALD operation, a CVD operation, an epitaxy operation, an oxidation operation, a plating operation, another type of deposition operation described in connection with FIG. 1, and/or another suitable deposition operation.

As shown in FIG. 5D, the light emitting laser diode 350 is formed in the cavity 504 (e.g., over and/or on the distributed Bragg reflection structure 352a). Forming the light emitting laser diode 350 may include the deposition tool 102 depositing layers of the light emitting laser diode 350 in an epitaxy operation (e.g., a selective epitaxial growth operation), a deposition operation described in connection with FIG. 1, and/or another suitable deposition operation.

Turning to FIG. 5E, the distributed Bragg reflection structure 352b is formed in the cavity 504 (e.g., over and/or on the light emitting laser diode 350). Forming the distributed Bragg reflection structure 352b may include the deposition tool 102 depositing layers of the distributed Bragg reflection structure 352b using one or more of a PVD operation, an ALD operation, a CVD operation, an epitaxy operation, an oxidation operation, a plating operation, another type of deposition operation described in connection with FIG. 1, and/or another suitable deposition operation. In some implementations, the planarization tool 110 removes the masking layer 502 after formation of the distributed Bragg reflection structure 352b.

As shown in FIG. 5F, the source/drain regions 324b are formed. As an example, the deposition tool 102, the exposure tool 104, the developer tool 106, the etch tool 108, and/or the ion implantation tool 114 may perform a combination of deposition, photolithography, etching, and/or implant operations to form the source/drain regions 324b. Additionally, or alternatively, the source/drain regions 324b may be formed in regions of the substrate layer 318b.

As shown in FIG. 5G, the dielectric region 308b is formed above and/or on the substrate layer 318b. As part of forming the dielectric region 308b, and as an example, the deposition tool 102 may deposit one or more dielectric layers of the dielectric region 308b using a CVD operation, a PVD operation, an ALD operation, another deposition operation described above in connection with FIG. 1, and/or another suitable deposition operation. In some implementations, the planarization tool 110 planarizes the one or more of the dielectric layers after the deposition tool 102 deposits the dielectric layers.

Additionally, or alternatively and as part of forming the dielectric region 308b, the deposition tool 102, the exposure tool 104, the developer tool 106, and/or the etch tool 108 may perform a combination of deposition, photolithography, and/or etching operations to form the interconnect structures 312b. The deposition tool 102 or the plating tool 112 may further form one or more of the metallization layers 310b. To form one or more of the metallization layers 310b, the deposition tool 102 and/or the plating tool 112 may deposit one or more of the metallization layers 310b in a CVD operation, a PVD operation, an ALD operation, an electroplating operation, another deposition operation described above in connection with FIG. 1, and/or another suitable deposition operation. In some implementations, the planarization tool 110 planarizes one or more of the metallization layers 310b after deposition.

In some implementations, the deposition tool 102, the exposure tool 104, the developer tool 106, and/or the etch tool 108 perform a combination of deposition, photolithography, and/or etching operations to form the ring-shaped etch block structure 356b from portions of the metallization layers 310b. Although shown as round in the detailed view (e.g., a top view) of FIG. 5G, a shape of the ring-shaped etch block structures 356b may be square, rectangular, elliptical, or another shape that may be suitable to aid in formation of a transmission region (e.g., the transmission region 354).

As indicated above, FIGS. 5A-5G are provided as an example. Other examples may differ from what is described with regard to FIGS. 5A-5G.

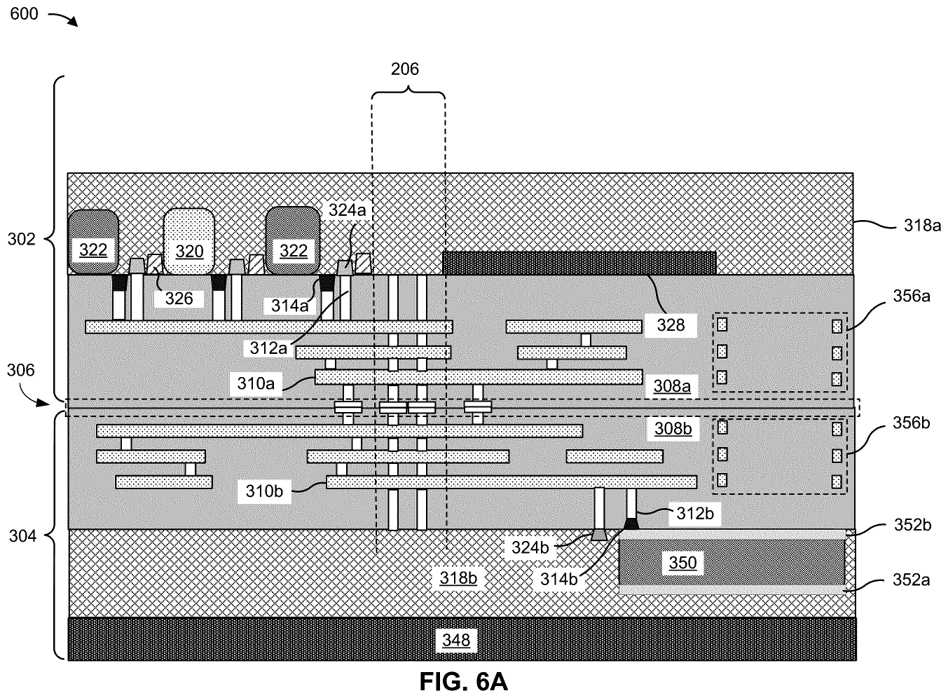

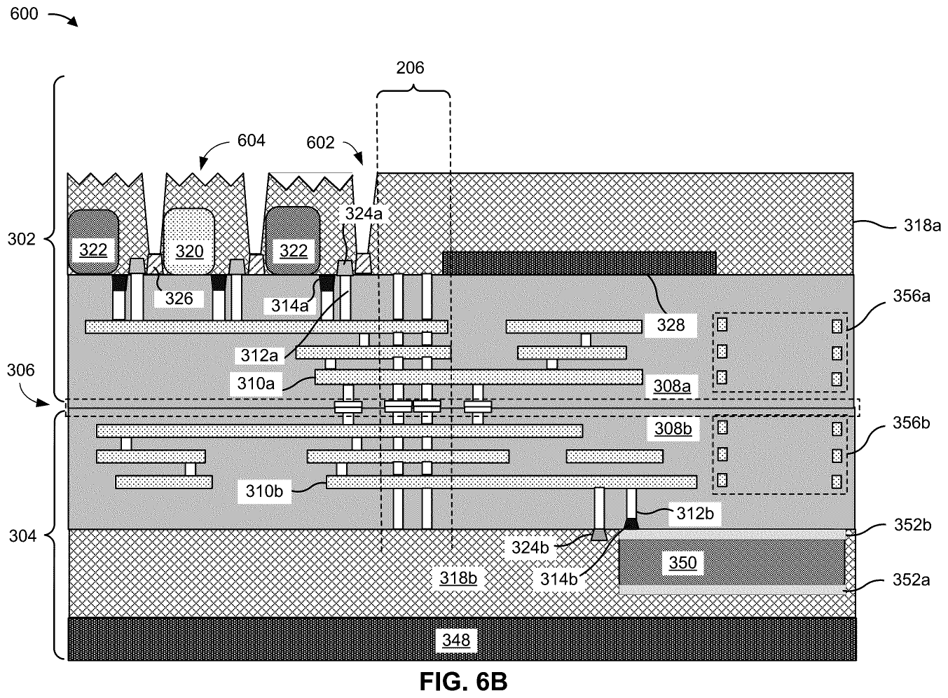

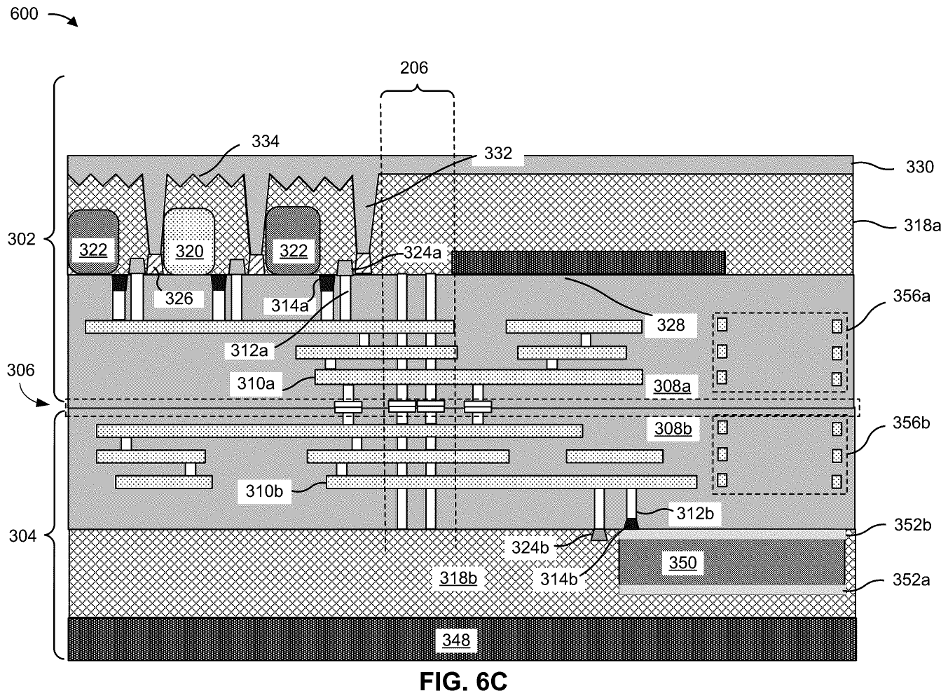

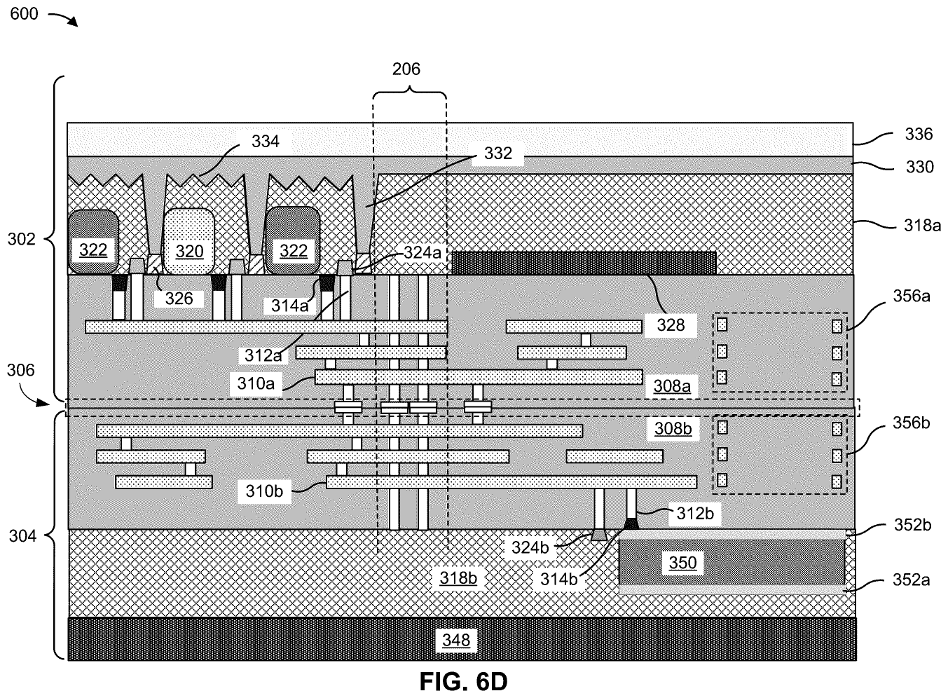

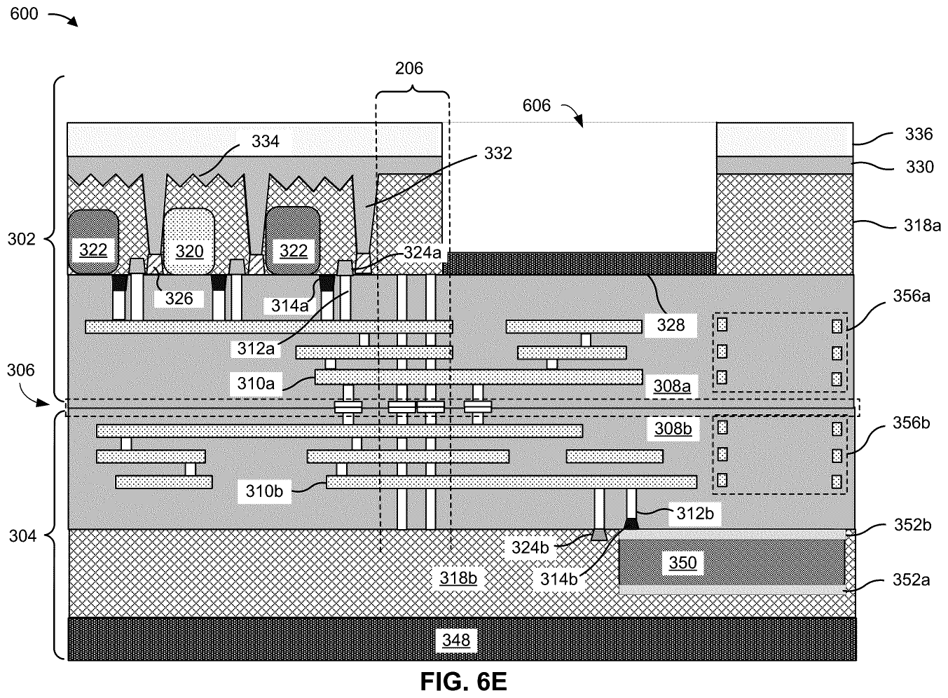

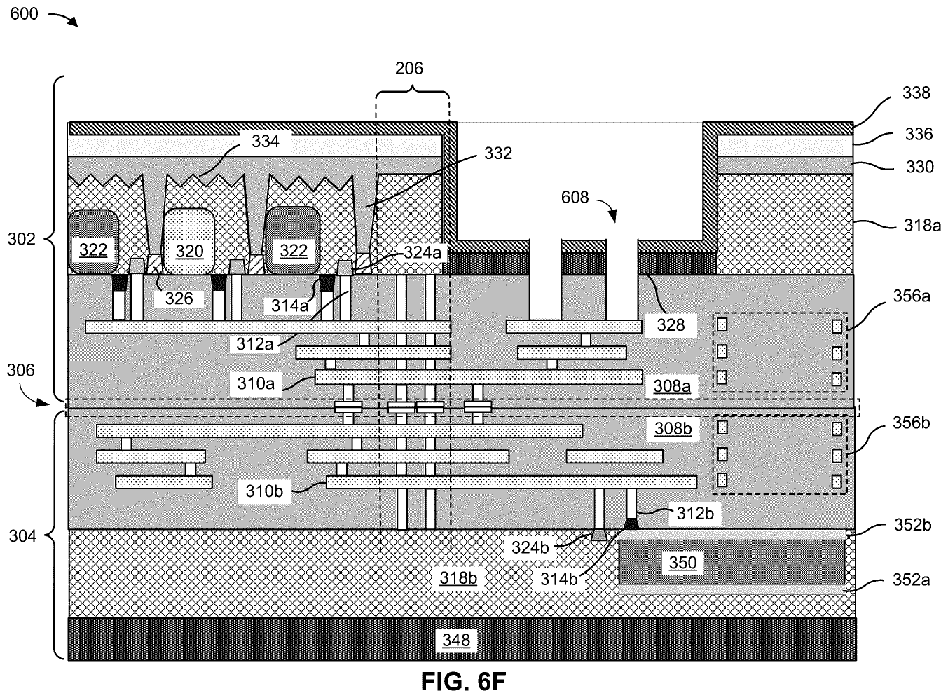

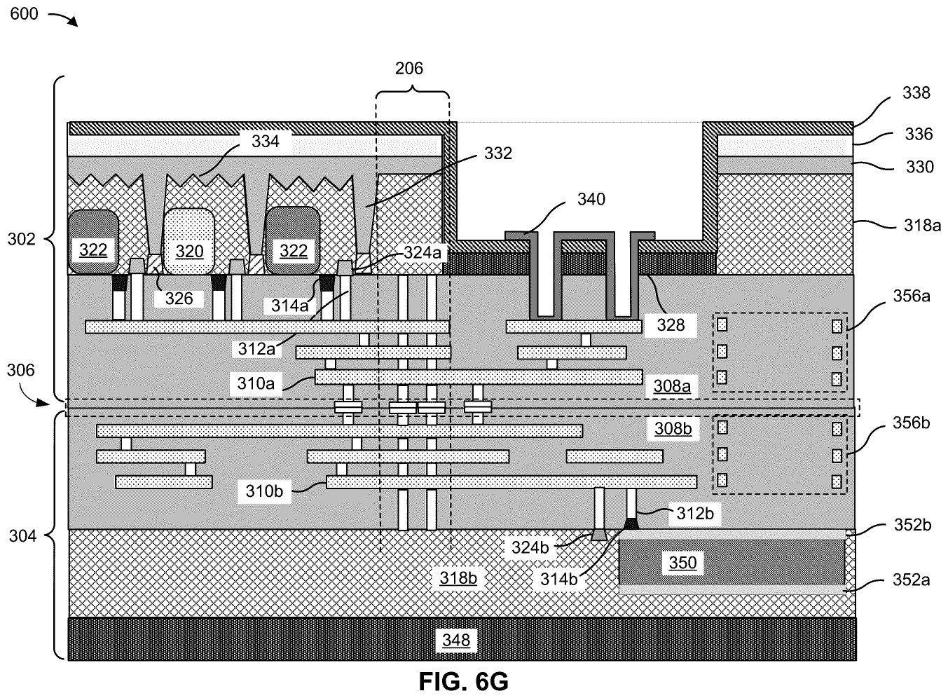

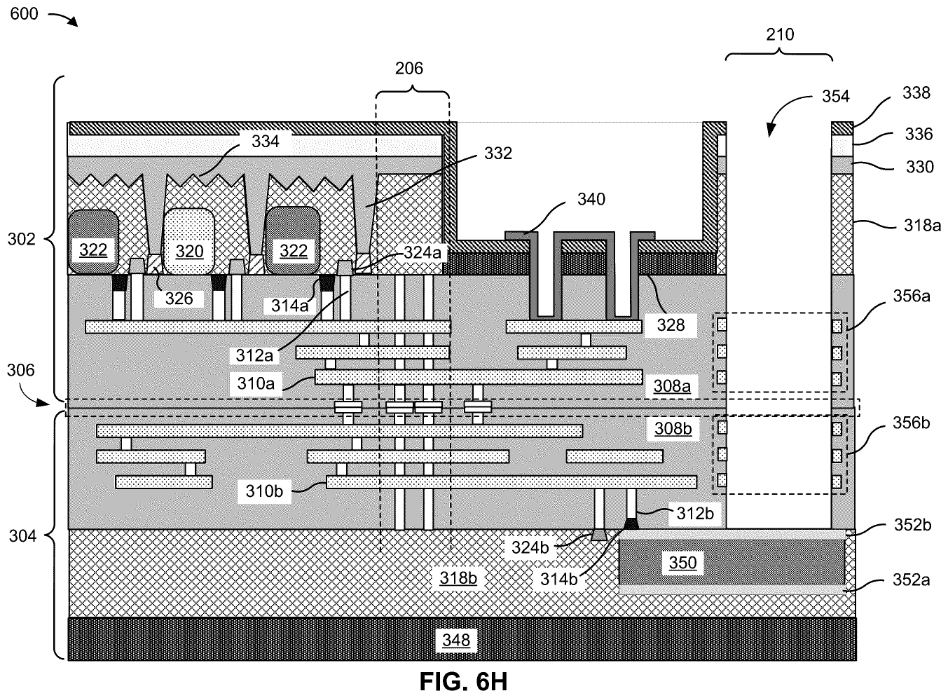

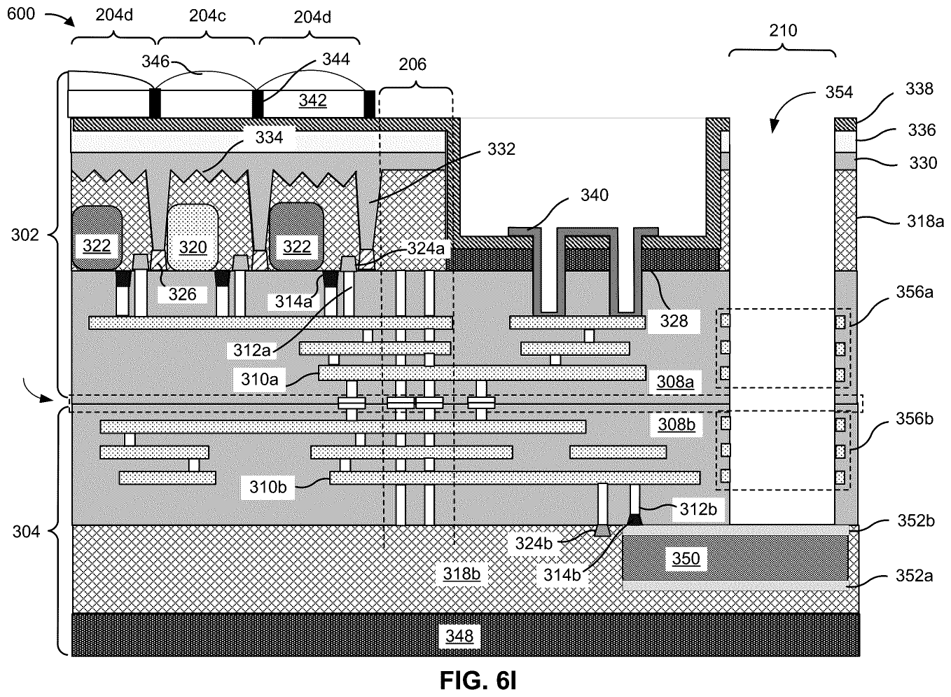

FIGS. 6A-6I are diagrams of an example implementation of joining portions of optoelectronic devices to form an optoelectronic device including a vertical-cavity surface emitting laser. Portions of the optoelectronic devices may correspond to portions of the optoelectronic device 300 as described in connection with FIG. 3, FIGS. 4A-4E, FIGS. 5A-5G, and elsewhere herein. As part of the implementation 600, a series of operations may be performed by one or more of the semiconductor processing tools 102-116 and/or the wafer/die transport tool 118 described in connection with FIG. 1.

As shown in FIG. 6A, the dielectric regions 308a and 308b are joined at the interface region 306. In some implementations, the dielectric region 308a and 308b include respective passivation layers (layers of an aluminum dioxide material (Al₂O₃), among other examples) that are joined with one another. In some implementations, the metallization layers 310a and 310b include bonding pad structures that are joined within the interface region 306. In some implementations, the bonding/debonding tool 116 performs a eutectic bonding operation, another bonding operation described above in connection with FIG. 1, and/or another suitable bonding operation.

Turning to FIG. 6B, and as part of the series of operations, the etch tool 108 forms cavities 602 (e.g., cavities for the DTI structures 332) and cavities 604 (e.g., cavities for the HA regions 334). In some implementations, a pattern in a photoresist layer is used to etch the substrate layer 318a to form the cavities 602 and 604. In these implementations, the deposition tool 102 forms the photoresist layer on the substrate layer 318a. The exposure tool 104 exposes the photoresist layer to a radiation source to pattern the photoresist layer. The developer tool 106 develops and removes portions of the photoresist layer to expose the pattern. The etch tool 108 etches the substrate layer 318a based on the pattern to form the cavities 602 and 604 in the substrate layer 318a. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the substrate layer 318a based on a pattern.

As shown in FIG. 6C, the oxide layer 330 is formed over and/or on the substrate layer 318a. The deposition tool 102 may deposit the oxide layer 330 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the oxide layer 330 after the deposition tool 102 deposits the oxide layer 330. As part of forming the oxide layer 330, the cavities 602 and 604 may be filled with oxide to form the DTI structures 332 and the HA regions 334. In some implementations, the deposition tool 102 deposits an anti-reflective (ARC) layer prior to depositing the oxide layer 330.

As shown in FIG. 6D, the oxide layer 336 is formed over and/or on the oxide layer 330. The deposition tool 102 may deposit the oxide layer 336 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the oxide layer 336 after the deposition tool 102 deposits the oxide layer 336.

Turning to FIG. 6E, and as part of the series of operations, a cavity 606 is formed through the oxide layer 336, the oxide layer 330, and the substrate layer 318a to the STI region 328. In some implementations, a pattern in a photoresist layer is used to etch the oxide layer 336, the oxide layer 330, and the substrate layer 318a to form the cavity 606. In these implementations, the deposition tool 102 forms the photoresist layer on the substrate layer 318a. The exposure tool 104 exposes the photoresist layer to a radiation source to pattern the photoresist layer. The developer tool 106 develops and removes portions of the photoresist layer to expose the pattern. The etch tool 108 etches the cavity 606 based on the pattern to form the cavity 606 in the oxide layer 336, the oxide layer 330, and the substrate layer 318a. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the oxide layer 336, the oxide layer 330, and the substrate layer 318a based on a pattern.

As shown in FIG. 6F, the oxide layer 338 is formed over and/or on the oxide layer 336. The deposition tool 102 may deposit the oxide layer 338 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the oxide layer 338 after the deposition tool 102 deposits the oxide layer 338.

As further shown in FIG. 6F, cavities 608 are formed through oxide layer 338, through the STI region 328, and into the dielectric region 308a. In some implementations, a pattern in a photoresist layer is used to etch the oxide layer 338, the STI region 328, and the dielectric region 308a to form the cavities 608. In these implementations, the deposition tool 102 forms the photoresist layer on the oxide layer 338. The exposure tool 104 exposes the photoresist layer to a radiation source to pattern the photoresist layer. The developer tool 106 develops and removes portions of the photoresist layer to expose the pattern. The etch tool 108 etches the oxide layer 338, the STI region 328, and the dielectric region 308a based on the pattern to form the cavities 608 through oxide layer 338, through the STI region 328, and into the dielectric region 308a. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the oxide layer 338, the STI region 328, and the dielectric region 308a based on a pattern.

As part of the series of operations and as shown in FIG. 6G, the bonding pad 340 is formed in the cavities 608. As an example, the deposition tool 102, the exposure tool 104, the developer tool 106, and/or the etch tool 108 may perform a combination of deposition, photolithography, and/or etching operations to form the bonding pad 340.

As shown in FIG. 6H, and as part of the series of operations, the transmission region 354 is formed through portions of the semiconductor devices 302 and 304. Forming the transmission region 354 may include forming a cavity through a center of the ring-shaped etch block structure 356a, through a center of the ring-shaped etch block structure 356b, and to a structure including the light emitting laser diode 350 (e.g., to a structure including the distributed Bragg reflection structure 352b and the light emitting laser diode 350).

In some implementations, a pattern in a photoresist layer is used to etch portions of the semiconductor devices 302 and 304 to form the transmission region 354. In these implementations, the deposition tool 102 forms the photoresist layer on the oxide layer 338. The exposure tool 104 exposes the photoresist layer to a radiation source to pattern the photoresist layer. The developer tool 106 develops and removes portions of the photoresist layer to expose the pattern. The etch tool 108 etches the semiconductor devices based on the pattern to form the transmission region in the semiconductor devices 302 and 304. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the semiconductor devices 302 and 304 based on a pattern.

During formation of the transmission region 354, the ring-shaped etch block structures 356a and 356b may inhibit lateral etching into the dielectric regions 308a and 308b. In this way, the ring-shaped etch block structures 356a and 356b aid in maintaining a targeted cross-sectional shape of the transmission region 354.

Further, and in some implementations after formation of the transmission region 354, the deposition tool 102 may form a protective layer on surfaces of the transmission region 354. For example, the deposition tool may coat surfaces of the transmissive region with a material that is reflective to NIR light (an indium tin oxide material (ITO), a tungsten oxide material (WO₃), or a metal material such as an aluminum (Al) material, among other examples. Furthermore, and in some implementations, the transmission region 354 includes a gaseous mixture such as air.

Turning to FIG. 6I, and as part of the series of operations, the filter layer 342, the grid structure 344, and the micro-lens layer 346 are formed over and/or on the oxide layer 338. As an example, the deposition tool 102, the exposure tool 104, the developer tool 106, and/or the etch tool 108 may perform a combination of deposition, photolithography, and/or etching operations to form the filter layer 342, the grid structure 344, and/or the micro-lens layer 346.

As indicated above, FIGS. 6A-6I are provided as an example. Other examples may differ from what is described with regard to FIGS. 6A-6I.

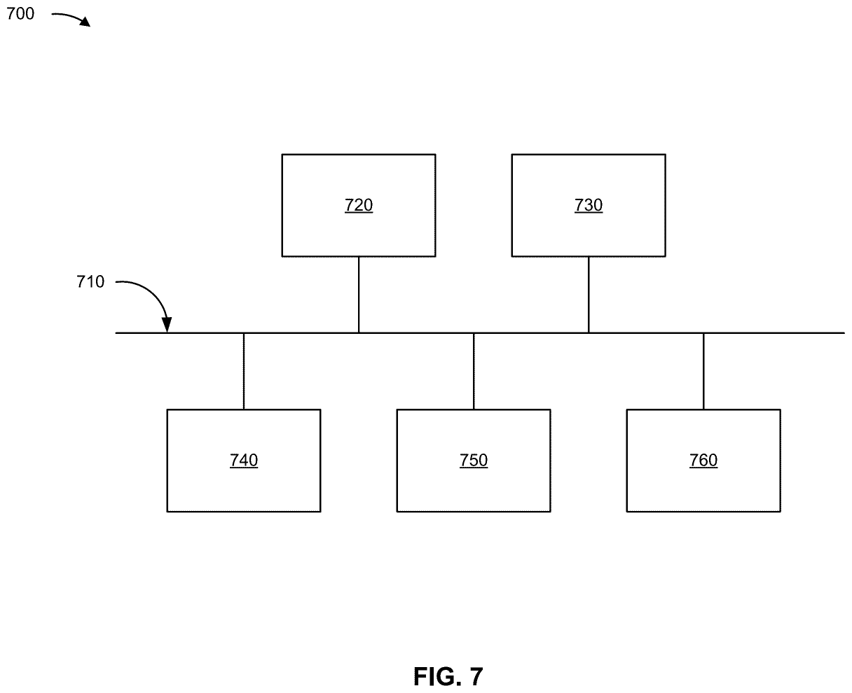

FIG. 7 is a diagram of example components of a device 700 associated with forming an optoelectronic device including a vertical-cavity surface emitting laser. The device 700 may correspond to one or more of the semiconductor processing tools 102-116 and/or the wafer/die transport tool 118. In some implementations, one or more of the semiconductor processing tools 102-116 and/or the wafer/die transport tool 118 may include one or more devices 700 and/or one or more components of the device 700. As shown in FIG. 7, the device 700 may include a bus 710, a processor 720, a memory 730, an input component 740, an output component 750, and/or a communication component 760.

The bus 710 may include one or more components that enable wired and/or wireless communication among the components of the device 700. The bus 710 may couple together two or more components of FIG. 7, such as via operative coupling, communicative coupling, electronic coupling, and/or electric coupling. For example, the bus 710 may include an electrical connection (e.g., a wire, a trace, and/or a lead) and/or a wireless bus. The processor 720 may include a central processing unit, a graphics processing unit, a microprocessor, a controller, a microcontroller, a digital signal processor, a field-programmable gate array, an application-specific integrated circuit, and/or another type of processing component. The processor 720 may be implemented in hardware, firmware, or a combination of hardware and software. In some implementations, the processor 720 may include one or more processors capable of being programmed to perform one or more operations or processes described elsewhere herein.

The memory 730 may include volatile and/or nonvolatile memory. For example, the memory 730 may include random access memory (RAM), read only memory (ROM), a hard disk drive, and/or another type of memory (e.g., a flash memory, a magnetic memory, and/or an optical memory). The memory 730 may include internal memory (e.g., RAM, ROM, or a hard disk drive) and/or removable memory (e.g., removable via a universal serial bus connection). The memory 730 may be a non-transitory computer-readable medium. The memory 730 may store information, one or more instructions, and/or software (e.g., one or more software applications) related to the operation of the device 700. In some implementations, the memory 730 may include one or more memories that are coupled (e.g., communicatively coupled) to one or more processors (e.g., processor 720), such as via the bus 710. Communicative coupling between a processor 720 and a memory 730 may enable the processor 720 to read and/or process information stored in the memory 730 and/or to store information in the memory 730.

The input component 740 may enable the device 700 to receive input, such as user input and/or sensed input. For example, the input component 740 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 750 may enable the device 700 to provide output, such as via a display, a speaker, and/or a light-emitting diode. The communication component 760 may enable the device 700 to communicate with other devices via a wired connection and/or a wireless connection. For example, the communication component 760 may include a receiver, a transmitter, a transceiver, a modem, a network interface card, and/or an antenna.

The device 700 may perform one or more operations or processes described herein. For example, a non-transitory computer-readable medium (e.g., memory 730) may store a set of instructions (e.g., one or more instructions or code) for execution by the processor 720. The processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, the processor 720 may be configured to perform one or more operations or processes described herein. Thus, implementations described herein are not limited to any specific combination of hardware circuitry and software.

The number and arrangement of components shown in FIG. 7 are provided as an example. The device 700 may include additional components, fewer components, different components, or differently arranged components than those shown in FIG. 7. Additionally, or alternatively, a set of components (e.g., one or more components) of the device 700 may perform one or more functions described as being performed by another set of components of the device 700.

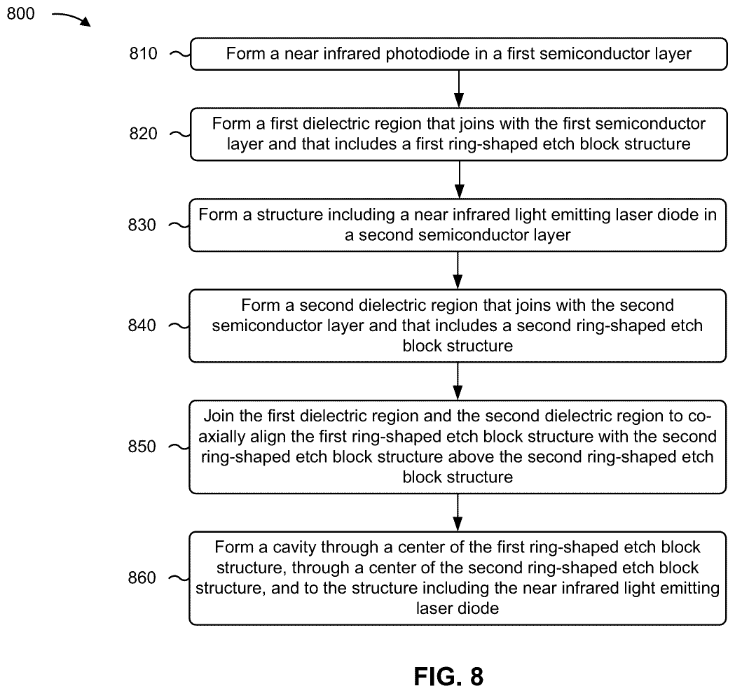

FIG. 8 is a flowchart of an example process 800 associated with forming an optoelectronic device including a vertical-cavity surface emitting laser. For example, the process 800 may form the optoelectronic device 300 of FIG. 3, including the light emitting laser diode 350 and the transmission region 354. In some implementations, one or more process blocks of FIG. 8 are performed by one or more semiconductor processing tools (e.g., one or more of the semiconductor processing tools 102-116). Additionally, or alternatively, one or more process blocks of FIG. 8 may be performed by one or more components of device 700, such as processor 720, memory 730, input component 740, output component 750, and/or communication component 760.

As shown in FIG. 8, process 800 may include forming an NIR light photodiode in a first semiconductor layer (block 810). For example, one or more of the semiconductor processing tools 102-116 of FIG. 1 may, using techniques described in connection with FIGS. 4A and 4B, form an NIR light photodiode in a first semiconductor layer (e.g., the photodiodes 322 formed in the substrate layer 318a). In some implementations, the NIR light photodiode includes a first type III or type V material.

As further shown in FIG. 8, process 800 may include forming a first dielectric region that joins with the first semiconductor layer and that includes a first ring-shaped etch block structure (block 820). For example, one or more of the semiconductor processing tools 102-116 of FIG. 1 may, using techniques described in connection with FIG. 4E, form a first dielectric region (e.g., the dielectric region 308a) that joins with the first semiconductor layer and that includes a first ring-shaped etch block structure (e.g., the ring-shaped etch block structure 356a), as described herein.

As further shown in FIG. 8, process 800 may include forming a structure including an NIR light emitting laser diode in a second semiconductor layer (block 830). For example, one or more of the semiconductor processing tools 102-116 may, using techniques described in connection with FIGS. 5B-5E, form a structure including an NIR light emitting laser diode in a second semiconductor layer (e.g., the light emitting laser diode 350 in the substrate layer 318b), as described herein. In some implementations, the NIR light emitting laser diode includes a second type III or type V material.

As further shown in FIG. 8, process 800 may include forming a second dielectric region that joins with the second semiconductor layer and that includes a second ring-shaped etch block structure (block 840). For example, one or more of the semiconductor processing tools 102-116 of FIG. 1 may, using techniques described in connection with FIG. 5G, may form a second dielectric region (e.g., the dielectric region 308b) that joins with the second semiconductor layer and that includes a second ring-shaped etch block structure (e.g., the ring-shaped etch block structure 356b), as described herein. In some implementations, the second ring-shaped etch block structure is above the structure including the NIR light emitting laser diode.

As further shown in FIG. 8, process 800 may include joining the first dielectric region and the second dielectric region to co-axially align the first ring-shaped etch block structure with the second ring-shaped etch block structure above the second ring-shaped etch block structure (block 850). For example, one or more of the semiconductor processing tools 102-116 may, using techniques described in connection with FIG. 6A, join the first dielectric region and the second dielectric region to co-axially align the first ring-shaped etch block structure with the second ring-shaped etch block structure above the second ring-shaped etch block structure, as described herein.

As further shown in FIG. 8, process 800 may include forming a cavity through a center of the first ring-shaped etch block structure, through a center of the second ring-shaped etch block structure, and to the structure including the NIR light emitting laser diode (block 860). For example, one or more of the semiconductor processing tools 102-116 may, using techniques described in connection with FIG. 6H, form a cavity (e.g., the transmission region 354) through a center of the first ring-shaped etch block structure, through a center of the second ring-shaped etch block structure, and to the structure including the NIR light emitting laser diode, as described herein.

Process 800 may include additional implementations, such as any single implementation or any combination of implementations described below and/or in connection with one or more other processes described elsewhere herein.

In a first implementation, forming the NIR light photodiode in the first semiconductor layer comprises forming a cavity (e.g., the cavity 406) in the first semiconductor layer, and depositing the first type III or type V material in the cavity using an epitaxial growth technique.

In a second implementation, alone or in combination with the first implementation, forming the structure that includes the NIR light emitting laser diode in the second semiconductor layer comprises forming a cavity (e.g., the cavity 504) in the second semiconductor layer, forming a first distributed Bragg reflection structure (e.g., the distributed Bragg reflection structure 352a) including a first silicon dioxide material in the cavity, forming the NIR light emitting laser diode by epitaxially growing the second type III or type V material over the first distributed Bragg reflection structure, and forming a second distributed Bragg reflection structure (e.g., the distributed Bragg reflection structure 352b) including a second silicon dioxide material over the NIR light emitting laser diode.

In a third implementation, alone or in combination with one or more of the first and second implementations, forming the first dielectric region that joins with the first semiconductor layer and that includes a first ring-shaped etch block structure includes using a sequence of metal deposition operations, photolithography patterning operations, and etching operations to form the first ring-shaped etch block structure from metal layers (e.g., the metallization layers 310a) interspersed within the first dielectric region.

In a fourth implementation, alone or in combination with one or more of the first through third implementations, forming the second dielectric region that joins with the second semiconductor layer and that includes the second ring-shaped etch block structure includes using a sequence of metal deposition operations, photolithography patterning operations, and etching operations to form the second ring-shaped etch block structure from metal layers (e.g., the metallization layers 310b) interspersed within the second dielectric region.

In a fifth implementation, alone or in combination with one or more of the first through fourth implementations, process 800 includes forming a lens (e.g., the micro-lens layer 346) over the NIR light photodiode.

In a sixth implementation, alone or in combination with one or more of the first through fifth implementations, process 800 includes filling the cavity with a gaseous compound that is transmissive to NIR light.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

Some implementations described herein include an optoelectronic device for a low-lighting application and techniques to form the optoelectronic device. The optoelectronic device includes NIR vertical-cavity surface emitting laser devices (VC-SEL devices), NIR pixel sensors, and VIS pixel sensors. The NIR VC-SEL devices and the NIR pixel sensor include selectively grown epitaxial materials (e.g., silicon germanium (SiGe), gallium arsenide (GaAs), or another type III/V material) that improves a performance of the NIR VC-SEL devices and the NIR pixel sensors.

Furthermore, the NIR VC-SEL devices, the NIR pixel sensors, and VIS pixel sensors are integrated in a single 3D-CIS device. By combining the NIR VC-SEL devices, the NIR pixel sensors, and the VIS pixel sensors into a single 3D-CIS device, a complexity and/or number of manufacturing operations to form the image detection system is lesser relative to the complexity and/or number of manufacturing operations to form another image detection system using discrete NIR VC-SEL devices, the NIR pixel sensors, and the VIS light pixel sensors.

In this way, a performance (e.g., a QE) of the optoelectronic device including the NIR VC-SEL devices, the NIR pixel sensors, and the VIS pixel sensors is improved relative to another optoelectronic device including doped, silicon-based photodiode devices and/or LED devices. Improving the performance of the optoelectronic device increases a manufacturing yield, of the optoelectronic device, to a particular performance threshold. Additionally, combining the NIR VC-SEL devices, the NIR pixel sensors, and the VIS pixel sensors into a single 3D-CIS device reduces an overall device space (e.g., silicon) and/or image detection system space. By increasing the manufacturing yield and consuming less device space and/or image detection system space, an amount of resources required to support a market that consumes a volume of the image detection system including the NIR VC-SEL devices, the NIR light photodiode devices, and the VIS photodiode devices (e.g. semiconductor manufacturing tools, labor, raw materials, and/or computing resources) is reduced.

As described in greater detail above, some implementations described herein provide an optoelectronic device. The optoelectronic device includes a first semiconductor device including a first layer of a first semiconductor material and an array of pixel structures. The pixel structures include an array of visible light photodiodes within the first layer of the first semiconductor material an array of NIR light photodiodes including a first epitaxial material and within the first layer of the first semiconductor material. In some implementations, the array of NIR light photodiodes is interspersed amongst the array of visible light photodiodes. The optoelectronic device includes a second semiconductor device joined with the first semiconductor device, below the first semiconductor device, and that includes a second layer of a second semiconductor material and a portion of an NIR light emitting structure. The NIR light emitting structure includes an NIR light emitting laser diode within the second semiconductor material that includes a second epitaxial material.

As described in greater detail above, some implementations described herein provide an optoelectronic device. The optoelectronic device includes a first layer of a first semiconductor material including an NIR light photodiode that includes a first epitaxial material. The optoelectronic device includes a first dielectric region below the NIR light photodiode and adjacent to the NIR light photodiode. The first dielectric region includes a first ring-shaped etch block structure. The optoelectronic device includes a second dielectric region below the first dielectric region. The second dielectric region includes a second ring-shaped etch block structure that is co-axially aligned with the first ring-shaped etch block structure. The optoelectronic device includes a second layer of a second semiconductor material below the second dielectric region. The second layer of the second semiconductor material includes an NIR light emitting laser diode that includes a second epitaxial material. The optoelectronic device includes an NIR light transmission region disposed through a center of the first ring-shaped etch block structure, through a center of the second ring-shaped etch block structure, and to a structure including the NIR light emitting laser diode.

As described in greater detail above, some implementations described herein provide a method. The method includes forming an NIR light photodiode in a first semiconductor layer, where the NIR light photodiode includes a first type III or type V material. The method includes forming a first dielectric region that joins with the first semiconductor layer and that includes a first ring-shaped etch block structure. The method includes forming a structure including an NIR light emitting laser diode in a second semiconductor layer, where the NIR light emitting laser diode includes a second type III or type V material. The method includes forming a second dielectric region that joins with the second semiconductor layer and that includes a second ring-shaped etch block structure, where the second ring-shaped etch block structure is above the structure including the NIR light emitting laser diode. The method includes joining the first dielectric region and the second dielectric region to co-axially align the first ring-shaped etch block structure with the second ring-shaped etch block structure above the second ring-shaped etch block structure. The method includes forming a cavity through a center of the first ring-shaped etch block structure, through a center of the second ring-shaped etch block structure, and to the structure including the NIR light emitting laser diode.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optoelectronic device, comprising:
a first semiconductor device comprising:
a first layer of a first semiconductor material; and
an array of pixel structures comprising:
an array of visible light photodiodes within the first layer of the first semiconductor material; and
an array of near infrared light photodiodes comprising a first epitaxial material and within the first layer of the first semiconductor material,
wherein the array of near infrared light photodiodes is interspersed amongst the array of visible light photodiodes;
a second semiconductor device joined with the first semiconductor device, below the first semiconductor device, and comprising:
a second layer of a second semiconductor material; and
a portion of a near infrared light emitting structure comprising:
a near infrared light emitting laser diode comprising a second epitaxial material and within the second layer of the second semiconductor material.

2. The optoelectronic device of claim 1, wherein the first epitaxial material and the second epitaxial material are a same selectively grown epitaxial material.

3. The optoelectronic device of claim 1, wherein the first epitaxial material and the second epitaxial material are different selectively grown epitaxial materials.

4. The optoelectronic device of claim 1, wherein the first epitaxial material or the second epitaxial material comprises:
a type III periodic element, or
a type V periodic element.

5. The optoelectronic device of claim 1, wherein the first epitaxial material or the second epitaxial material comprises:
a germanium material;
a silicon germanium material;
a gallium arsenide material; or
an indium phosphide material.

6. The optoelectronic device of claim 1, further comprising:
a seal ring structure between the array of near infrared light photodiodes and the portion of the near infrared light emitting structure.

7. The optoelectronic device of claim 1, wherein the portion of the near infrared light emitting structure further comprises:
a first distributed Bragg reflection structure below the near infrared light emitting laser diode and,
a second distributed Bragg reflection structure above the near infrared light emitting laser diode.

8. The optoelectronic device of claim 1, wherein the first semiconductor device comprises:
a system-on-chip type of semiconductor device, and
wherein the second semiconductor device comprises:
an application-specific integrated circuit type of semiconductor device joined with a vertical-cavity surface emitting laser type of semiconductor device.

9. An optoelectronic device, comprising:
a first layer of a first semiconductor material comprising:
a near infrared light photodiode comprising a first epitaxial material;
a first dielectric region below the near infrared light photodiode, adjacent to the near infrared light photodiode, and comprising:
a first ring-shaped etch block structure;
a second dielectric region below the first dielectric region and comprising:
a second ring-shaped etch block structure that is co-axially aligned with the first ring-shaped etch block structure;
a second layer of a second semiconductor material below the second dielectric region and comprising:
a near infrared light emitting laser diode comprising a second epitaxial material; and
a near infrared light transmission region disposed through a center of the first ring-shaped etch block structure, through a center of the second ring-shaped etch block structure, and to a structure including the near infrared light emitting laser diode.

10. The optoelectronic device of claim 9, wherein the first ring-shaped etch block structure comprises:
portions of one or more metal layers interspersed within the first dielectric region.

11. The optoelectronic device of claim 9, wherein the second ring-shaped etch block structure comprises:
portions of one or more metal layers interspersed within the second dielectric region.

12. The optoelectronic device of claim 9, wherein the near infrared light transmission region comprises:
a gaseous mixture that is disposed through the center of the first ring-shaped etch block structure, through the center of the second ring-shaped etch block structure, and to the structure including the near infrared light emitting laser diode.

13. The optoelectronic device of claim 9, wherein the near infrared light transmission region intersects with a distributed Bragg reflection structure over the near infrared light emitting laser diode.

14. A method, comprising:
forming a near infrared light photodiode in a first semiconductor layer,
wherein the near infrared light photodiode includes a first type III or type V material;
forming a first dielectric region that joins with the first semiconductor layer and that includes a first ring-shaped etch block structure;
forming a structure including a near infrared light emitting laser diode in a second semiconductor layer,
wherein the near infrared light emitting laser diode includes a second type III or type V material;
forming a second dielectric region that joins with the second semiconductor layer and that includes a second ring-shaped etch block structure,
wherein the second ring-shaped etch block structure is above the structure including the near infrared light emitting laser diode;
joining the first dielectric region and the second dielectric region to co-axially align the first ring-shaped etch block structure with the second ring-shaped etch block structure above the second ring-shaped etch block structure; and
forming a cavity through a center of the first ring-shaped etch block structure, through a center of the second ring-shaped etch block structure, and to the structure including the near infrared light emitting laser diode.

15. The method of claim 14, wherein forming the near infrared light photodiode in the first semiconductor layer comprises:
forming a cavity in the first semiconductor layer; and
depositing the first type III or type V material in the cavity using an epitaxial growth technique.

16. The method of claim 14, wherein forming the structure that includes the near infrared light emitting laser diode in the second semiconductor layer comprises:
forming a cavity in the second semiconductor layer;
forming a first distributed Bragg reflection structure including a first silicon dioxide material in the cavity;
forming the near infrared light emitting laser diode by epitaxially growing the second type III or type V material over the first distributed Bragg reflection structure; and
forming a second distributed Bragg reflection structure including a second silicon dioxide material over the near infrared light emitting laser diode.

17. The method of claim 14, wherein forming the first dielectric region that joins with the first semiconductor layer and that includes a first ring-shaped etch block structure comprises:
using a sequence of metal deposition operations, photolithography patterning operations, and etching operations to form the first ring-shaped etch block structure from metal layers interspersed within the first dielectric region.

18. The method of claim 14, wherein forming the second dielectric region that joins with the second semiconductor layer and that includes the second ring-shaped etch block structure comprises:
using a sequence of metal deposition operations, photolithography patterning operations, and etching operations to form the second ring-shaped etch block structure from metal layers interspersed within the second dielectric region.

19. The method of claim 16, further comprising:
forming a lens over the near infrared light photodiode.

20. The method of claim 16, further comprising:
filling the cavity with a gaseous compound that is transmissive to near infrared light.
